(19) United States
(12) Patent Application Publication
(10) Pub. No.: US 2024/0283428 A1
(43) Pub. Date: Aug. 22, 2024

(54) CAPACITIVELY-COUPLED RESONATOR FOR IMPROVEMENT IN UPPER BAND EDGE STEEPNESS

(71) Applicant: Murata Manufacturing Co., Ltd., Nagaokakyo-shi (JP)

(72) Inventors: Andrew Guyette, San Mateo, CA (US); Pintu Adhikari, San Mateo, CA (US); Santhosh Gottuparthy, Sunnyvale, CA (US); Wei Yang, Goleta, CA (US)

(21) Appl. No.: 18/444,030

(22) Filed: Feb. 16, 2024

Related U.S. Application Data
(60) Provisional application No. 63/486,063, filed on Feb. 21, 2023.
(60) Provisional application No. 63/536,131, filed on Sep. 1, 2023.

(51) Int. Cl. H03H 9/54; H03H 3/02; H03H 9/02; H03H 9/17; H03H 9/56

(52) U.S. Cl. CPC H03H 9/542; H03H 3/02; H03H 9/02228; H03H 9/173; H03H 9/564; H03H 9/566; H03H 2003/021

(57) ABSTRACT

A filter is provided that includes resonators connected in series between first and second ports. Each of the resonators includes a piezoelectric layer; and an interdigital transducer (IDT) having a plurality of interleaved fingers at a surface of the piezoelectric layer. The piezoelectric layer and the IDT are configured such that a radio frequency signal applied to the IDT excites a primary shear acoustic mode in the piezoelectric layer. The filter includes a capacitor connected between ground and a node between the first bulk acoustic resonator and the second bulk acoustic resonator.

### CROSS REFERENCE TO RELATED APPLICATIONS

This application claims priority to U.S. Patent Provisional Application No. 63/486,063, filed Feb. 21, 2023, and to U.S. Patent Provisional Application No. 63/536,131, filed Sep. 1, 2023, the entire contents of each of which are hereby incorporated by reference.

### TECHNICAL FIELD

This disclosure relates to radio frequency filters using acoustic wave resonators, and, more, specifically, to filters for use in communications equipment.

### BACKGROUND

A radio frequency (RF) filter is a two-port device configured to pass some frequencies and to stop other frequencies, where “pass” means transmit with relatively low signal loss and “stop” means block or substantially and/or predominantly attenuate. The range of frequencies passed by a filter is referred to as the “pass-band” of the filter. The range of frequencies stopped by such a filter is referred to as the “stop-band” of the filter. A typical RF filter has at least one pass-band and at least one stop-band. Specific requirements on a pass-band or stop-band may depend on the specific application. For example, in some cases a “pass-band” may be defined as a frequency range where the insertion loss of a filter is better than a defined value such as 1 dB, 2 dB, or 3 dB, while a “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front-ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

Performance enhancements to the RF filters in a wireless system can have a broad impact to system performance. Improvements in RF filters can be leveraged to provide system performance improvements, such as larger cell size, longer battery life, higher data rates, greater network capacity, lower cost, enhanced security, higher reliability, etc. These improvements can be realized at many levels of the wireless system both separately and in combination, for example, at the RF module, RF transceiver, mobile or fixed sub-system, or network levels. As the demand for RF filters operating at higher frequencies continues to increase, there is a need for improved filters that can operate at different frequency bands while also improving the manufacturing processes for making such filters.

### SUMMARY

In some aspects, the techniques described herein relate to a filter, including a plurality of bulk acoustic resonators; and a capacitor connected to ground. The capacitor bisecting a series connection between at least two acoustic sub-resonators of the plurality of bulk acoustic resonators. Effectively, the capacitor provides a pole for the bulk acoustic resonator that lands at the upper band edge of filter device, i.e., that has the lowest anti-resonance frequency of the plurality of bulk acoustic resonators connected in series as described herein. As a result, the high edge passband (UBE) of the filter device is configured with an increased steepness.

Thus, according to an exemplary aspect, a filter device is provided that includes a first port and a second port; a first bulk acoustic resonator and a second bulk acoustic resonator connected in series between the first port and the second port, each of the first and second bulk acoustic resonators comprising a piezoelectric layer; and an interdigital transducer (IDT) having a plurality of interleaved fingers at a surface of the piezoelectric layer; and a capacitor connected between ground and a node between the first bulk acoustic resonator and the second bulk acoustic resonator. In this aspect, the piezoelectric layer and the IDT are configured such that a radio frequency signal applied to the IDT excites a primary shear acoustic mode in the piezoelectric layer.

In another exemplary aspect, each of the first bulk acoustic resonator and the second bulk acoustic resonator comprises a pair of sub-resonators that each have a same stack as each other.

In another exemplary aspect, the filter device further comprises a pair of additional capacitors that are connected in parallel to the pair of sub-resonators, respectively. Moreover, in an aspect, the pair of additional capacitors each have a capacitance greater than the capacitor connected between the ground and the node between the first and second bulk acoustic resonators.

In another exemplary aspect, the capacitor has a capacitance in a range of 0.0001 pF to 0.25 pF.

In another exemplary aspect, the capacitor is connected in shunt with the first and second bulk acoustic resonators.

In another exemplary aspect, the capacitor has a first conductor and a second conductor with the first conductor and the second conductor being separated by a gap having a distance in a range of 10 μm to 20 μm. Moreover, in this aspect, at least a portion of the first conductor and at least a portion of the second conductor can be disposed on a piezoelectric layer, wherein the piezoelectric layer includes an etched region beneath the gap.

In another exemplary aspect, the capacitor is an interdigital capacitor comprising a plurality of interdigitated capacitive fingers that extend in a direction substantially orthogonal to a direction of the plurality of interleaved fingers of the IDT.

In another exemplary aspect, the primary shear acoustic mode is a bulk shear mode where acoustic energy propagates along a direction substantially and/or predominantly orthogonal to the surface of the piezoelectric layer and transverse to a direction of an electric field created by the IDT.

Moreover, in another exemplary aspect of the filter device, each of the first and second bulk acoustic resonators further comprises a substrate; and a dielectric layer disposed on the substrate and having a cavity disposed therein, wherein the piezoelectric layer includes a diaphragm over the cavity, and wherein the IDT is disposed at a surface of the diaphragm that is opposite the cavity.

In another exemplary aspect, the filter device further comprise at least one additional bulk acoustic resonator coupled in shunt between the first and second bulk acoustic resonators and coupled in parallel to the capacitor.

According to an exemplary aspect, a filter device is provided that includes a first plurality bulk acoustic resonators connected in series between a pair of ports; a second plurality of bulk acoustic resonators connected in shunt with the first plurality of bulk acoustic resonators; and a capacitor connected in shunt between ground and one bulk acoustic resonator of the plurality of bulk acoustic resonators that has a lowest anti-resonance frequency of the plurality of bulk acoustic resonators connected in series. In this aspect, each of the bulk acoustic resonators comprises a piezoelectric layer; and an interdigital transducer (IDT) having a plurality of interleaved fingers at a surface of the piezoelectric layer. Moreover, the piezoelectric layer and the IDT can be configured such that a radio frequency signal applied to the IDT excites a primary shear acoustic mode in the piezoelectric layer.

In yet another exemplary aspect, a radio frequency module is provided that includes a radio frequency circuit; and a filter device coupled to the radio frequency circuit, the filter device and the radio frequency circuit being enclosed within a common package. In this aspect, the filter device comprises a first port and a second port; a first bulk acoustic resonator and a second bulk acoustic resonator connected in series between the first port and the second port, each of the first and second bulk acoustic resonators comprising a piezoelectric layer, and an interdigital transducer (IDT) having a plurality of interleaved fingers at a surface of the piezoelectric layer; and a capacitor connected between ground and a node between the first bulk acoustic resonator and the second bulk acoustic resonator. Moreover, the piezoelectric layer and the IDT are configured such that a radio frequency signal applied to the IDT excites a primary shear acoustic mode in the piezoelectric layer.

The above simplified summary of example aspects serves to provide a basic understanding of the present disclosure. This summary is not an extensive overview of all contemplated aspects and is intended to neither identify key or critical elements of all aspects nor delineate the scope of any or all aspects of the present disclosure. Its sole purpose is to present one or more aspects in a simplified form as a prelude to the more detailed description of the disclosure that follows. To the accomplishment of the foregoing, the one or more aspects of the present disclosure include the features described and exemplarily pointed out in the claims.

### BRIEF DESCRIPTION OF THE DRAWINGS

The accompanying drawings, which are incorporated into and form a part of this specification, illustrate one or more example aspects of the present disclosure and, together with the detailed description, serve to explain their principles and implementations.

FIG. 1A includes a schematic plan view and two schematic cross-sectional views of a transversely-excited film bulk acoustic resonator (XBAR).

FIG. 1B shows a schematic cross-sectional view of an alternative configuration of an XBAR.

FIG. 2A is an expanded schematic cross-sectional view of a portion of the XBAR of FIG. 1A.

FIG. 2B is an expanded schematic cross-sectional view of an alternative configuration of the XBAR of FIG. 1A.

FIG. 2C is an expanded schematic cross-sectional view of another alternative configuration of the XBAR of FIG. 1A.

FIG. 2D is an expanded schematic cross-sectional view of another alternative configuration of the XBAR of FIG. 1A.

FIG. 2E is an expanded schematic cross-sectional view of a portion of a solidly-mounted XBAR (SM XBAR).

FIG. 3A is a schematic cross-sectional view of an XBAR according to an exemplary aspect.

FIG. 3B is an alternative schematic cross-sectional view of an XBAR according to an exemplary aspect.

FIG. 4 is a graphic illustrating a shear horizontal acoustic mode in an XBAR.

FIG. 5A is a schematic block diagram of a filter using XBARs of FIGS. 1A and/or 1B.

FIG. 5B is a schematic diagram of a radio frequency module that includes an acoustic wave filter device according to an exemplary aspect.

FIG. 6 is a high-level schematic diagram of a filter device including a capacitively-coupled resonator according to an exemplary aspect.

FIG. 7 is a detailed schematic diagram of a filter device including a capacitively-coupled resonator according to an exemplary aspect.

FIG. 8 is an illustration of a graph depicting a frequency response of a capacitively-coupled resonator as shown in FIG. 7.

FIGS. 9A to 9C illustrate graphical illustrations of different circuit layouts of a capacitively-coupled resonator according to exemplary aspects.

FIG. 10 is a graphical illustration of waveforms depicting a frequency response for each circuit layout of the capacitively-coupled resonator of FIGS. 9A to 9C.

FIG. 11A is another high-level schematic diagram of a filter device including a capacitively-coupled resonator according to an exemplary aspect.

FIG. 11B is a graphical illustration of waveforms depicting a frequency response for the circuit layout of the filter device of FIG. 11A compared to an implementation without the capacitively-coupled resonator.

FIG. 12 is another high-level schematic diagram of a filter device including an IDC as the capacitively-coupled resonator according to an exemplary aspect.

FIG. 13 is an illustration of a graph depicting a frequency response of a capacitively-coupled resonator as shown in FIG. 12.

FIG. 14 illustrates a flowchart of a method of manufacturing a filter as described herein according to an exemplary aspect.

Throughout this description, elements appearing in figures are assigned three-digit or four-digit reference designators, where the two least significant digits are specific to the element and the one or two most significant digit is the figure number where the element is first introduced. An element that is not described in conjunction with a figure may be presumed to have the same characteristics and function as a previously described element having the same reference designator.

### DETAILED DESCRIPTION

A transversely-excited film bulk acoustic resonator (XBAR) is a resonator structure for use in microwave filters. As described in detail below, an XBAR device includes an IDT formed on a piezoelectric material or layer (e.g., a plate). A microwave signal applied to the IDT excites a shear primary acoustic wave in the piezoelectric diaphragm, such that the acoustic energy flows substantially and/or predominantly normal to the surfaces of the layer, which is orthogonal or transverse to the direction of the electric field generated by the IDT. XBAR resonators provide very high electromechanical coupling and high frequency capability.

As described according to exemplary aspects below, a radio frequency (RF) filter may incorporate multiple XBAR devices connected as a conventional ladder filter circuit. A ladder filter circuit includes one or more series resonator connected in series between an input and an output of the filter and one or more shunt resonators, each connected between ground and one of the input, the output, or a node between two series resonators. Each resonator has a resonance frequency where the admittance of the resonator approaches that of a short circuit, and an anti-resonance frequency where the admittance of the resonator approaches that of an open circuit. In a typical ladder band-pass filter circuit, the resonant frequencies of shunt resonators are located below a lower edge of a passband of the filter and the resonant frequencies of series resonators are located in the passband.

The dominant parameter that determines the resonance frequency of an XBAR is the thickness of the piezoelectric membrane or diaphragm suspended over a cavity. Resonance frequency also depends, to a lesser extent, on the pitch and width, or mark, of the IDT fingers. Many filter applications require resonators with a range of resonance and/or anti-resonant frequencies beyond the range that can be achieved by varying the pitch of the IDTs.

According to an exemplary aspect, a capacitively-coupled resonator is a type of resonator that uses capacitive coupling to transfer energy between two or more resonant elements. According to the exemplary aspect, the capacitive cross coupling can be used to improve the upper band edge (UBE) steepness, which refers to the resonator's ability to maintain its resonant frequency over a range of applied loads or stresses. In a capacitively-coupled resonator, the resonant elements are typically two or more parallel plates that are separated by a dielectric material. The plates are connected to an electrical circuit, and an AC voltage is applied to them, creating an electrical field between the plates. The resonant elements are mechanically coupled through the dielectric material, and the energy is transferred between them through the electrical field.

Capacitively-coupled resonators can be used to improve UBE steepness because they have a higher Q (i.e., quality factor) and a lower resonant frequency compared to other types of resonators. Capacitively-coupled resonators are used in a variety of applications, including filters, oscillators, sensors, and actuators. They can be made using a variety of materials and fabrication techniques, and they can be designed to operate over a wide frequency range.

However, it is quite challenging to increase the steepness in filter response without increasing the number of stages (i.e., more resonator sections) and/or resonators of a filter or without increasing the area of the filter. Adding an additional pole at the UBE can improve the capacitively-coupled resonator's upper band edge stiffness. This configuration allows them to maintain their resonant frequency over a wider range of applied loads or stresses, making them more robust and stable.

By adding a capacitor connected in shunt with series resonators, an additional pole can be provided at the UBE according to an exemplary aspect. Moreover, such a configuration will enable the steepness of the UBE of the filter to be improved (i.e., more vertical) without increasing the number of stages or die size of the overall filter. Thus, as described in detail below, the configuration can be provided for placing a capacitor connected in shunt to a node that bisects the series connection between resonators and connecting the capacitor to ground. The additional element (e.g., a shunt capacitor or cross-coupling capacitor) can have its own resonant frequency, and the combination of the elements can create an additional pole at the upper band edge.

The exemplary aspects described herein provide for technical advantages over other approaches used to create an additional pole at the UBE to improve UBE steepness. For example, the topology of the capacitively-coupled resonator with the added capacitor creates the additional pole at the UBE without increasing the number of stages or die size of a filter. The topology of the capacitively-coupled resonator also is less sensitive compared to other circuit topologies that can create an additional pole at the UBE. Additionally, all resonators in the capacitively-coupled resonator topology can be identical, such as by using the same stack. According to exemplary aspects, the exemplary filter configurations can be implemented using various types of XBAR devices as described as follows.

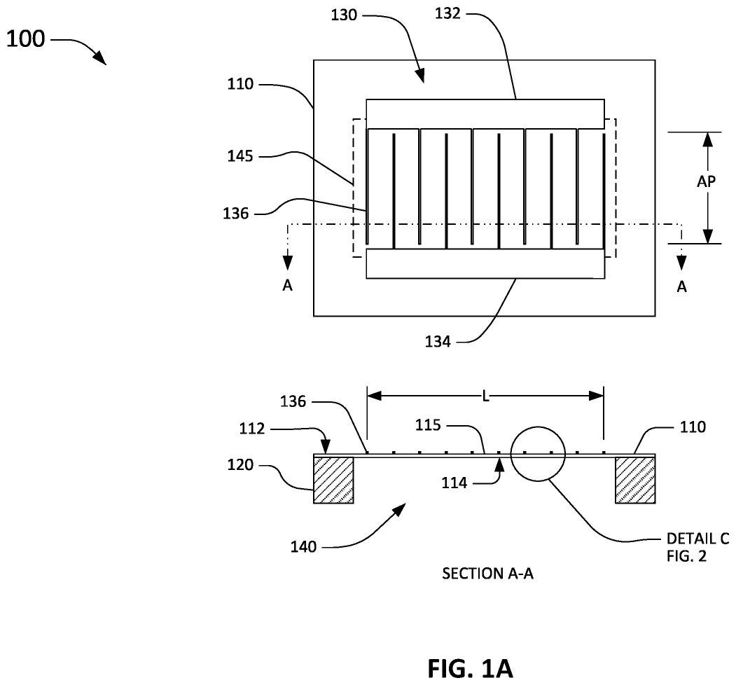

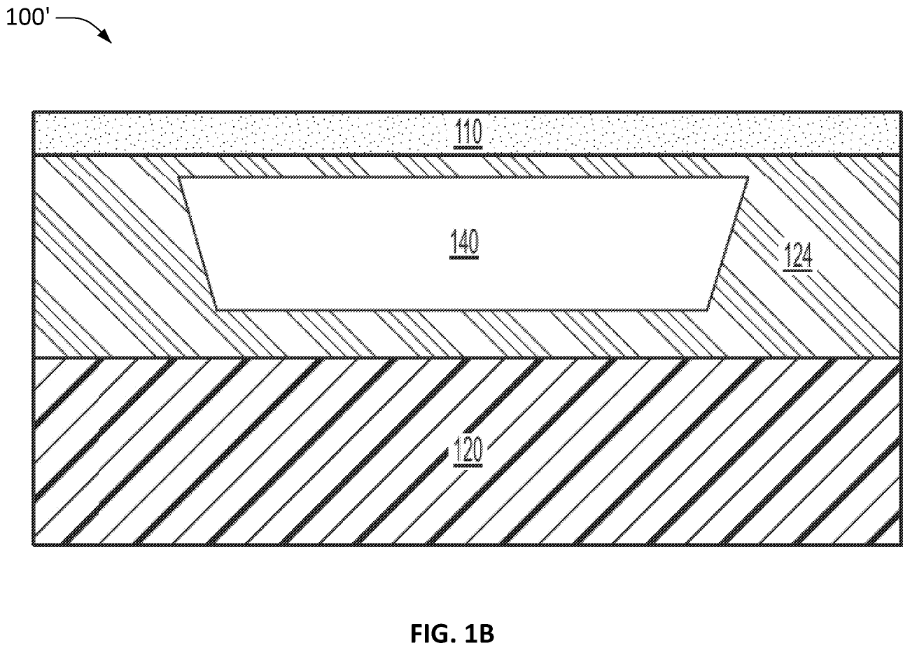

In particular, FIG. 1A shows a simplified schematic top view and orthogonal cross-sectional views of a bulk acoustic resonator device, namely a transversely excited film bulk acoustic resonator (XBAR) 100. XBAR resonators, such as the resonator 100, may be used in a variety of RF filters including band-reject filters, band-pass filters, duplexers, and multiplexers. XBARs are particularly suited for use in filters for communications bands with frequencies above 3 GHz.

In general, the XBAR 100 is made up of a thin film conductor pattern formed at one or both surfaces of a piezoelectric layer 110 (herein piezoelectric plate or piezoelectric layer may be used interchangeably) having parallel, or substantially and/or predominantly parallel, front side 112 and a back side 114, respectively (also referred to generally first and second surfaces, respectively). It should be appreciated that the term “parallel” generally refers to the front side 112 and back side 114 being opposing to each other and that the surfaces are not necessarily planar and parallel to each other. For example, to the manufacturing variances result from the deposition process, the front side 112 and back side 114 may have undulations of the surface as would be appreciated to one skilled in the art.

According to an exemplary aspect, the piezoelectric layer is a thin single-crystal layer of a piezoelectric material, such as lithium niobate, lithium tantalate, lanthanum gallium silicate, gallium nitride, or aluminum nitride. It should be appreciated that the term “single-crystal” does not necessarily mean entirely of a uniform crystalline structure and may include impurities due to manufacturing variances as long as the crystal structure is within acceptable tolerances. The piezoelectric layer is cut such that the orientation of the X, Y, and Z crystalline axes with respect to the front and back sides is known and consistent. In the examples described herein, the piezoelectric layers are Z-cut, which is to say the Z axis is normal to the front and back sides 112, 114. However, XBARs may be fabricated on piezoelectric layers with other crystallographic orientations including rotated Z-cut, Z-cut and rotated YX cut.

The Y-cut family, such as 120Y and 128Y, are typically referred to as 120YX or 128YX, where the “cut angle” is the angle between the y axis and the normal to the layer. The “cut angle” is equal to β+90°. For example, a layer with Euler angles [0°, 30°, 0° ] is commonly referred to as “120° rotated Y-cut” or “120Y.” Thus, the Euler angles for 120YX and 128YX are (0, 120-90,0) and (0, 128-90,0) respectively. A “Z-cut” is typically referred to as a ZY cut and is understood to mean that the layer surface is normal to the Z axis but the wave travels along the Y axis. The Euler angles for ZY cut are (0, 0, 90).

The back side 114 of the piezoelectric layer 110 may be at least partially supported by a surface of the substrate 120 except for a portion of the piezoelectric layer 110 that forms a diaphragm 115 that is over (e.g., spanning or extending over in the thickness direction) a cavity 140 in one or more layers below the piezoelectric layer 110 such as one or more intermediate layers above or in the substrate. In other words, the back side 114 of the piezoelectric layer 110 can be coupled or connected either directly or indirectly, via one or more intermediate layers (e.g., a dielectric layer), to a surface of the substrate 120. Moreover, the phrase “supported by” or “attached” may, as used herein interchangeably, mean attached directly, attached indirectly, mechanically supported, structurally supported, or any combination thereof. The portion of the piezoelectric layer that is over (e.g., spanning or extending over) the cavity can be referred to herein as a “diaphragm” 115 due to its physical resemblance to the diaphragm of a microphone. As shown in FIG. 1A, the diaphragm 115 is contiguous with the rest of the piezoelectric layer 110 around all of a perimeter 145 of the cavity 140. In this context, “contiguous” means “continuously connected without any intervening item”. However, the diaphragm 115 can be configured with at least 50% of the edge surface of the diaphragm 115 coupled to the edge of the piezoelectric layer 110 in an exemplary aspect.

According to the exemplary aspect, the substrate 120 is configured to provide mechanical support to the piezoelectric layer 110. The substrate 120 may be, for example, silicon, sapphire, quartz, or some other material or combination of materials. The back side 114 of the piezoelectric layer 110 may be bonded to the substrate 120 using a wafer bonding process. Alternatively, the piezoelectric layer 110 may be grown on the substrate 120 or supported by, or attached to, the substrate in some other manner.

For purposes of this disclosure, “cavity” has its conventional meaning of “an empty space within a solid body.” The cavity 140 may be a hole completely through the substrate 120 (as shown in Section A-A), a hole within a dielectric layer (as shown in FIG. 1B), or a recess in the substrate 120. The cavity 140 may be formed, for example, by selective etching of the substrate 120 before or after the piezoelectric layer 110 and the substrate 120 are attached, either directly or indirectly.

As shown, the conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved with each other. At least a portion of the interleaved fingers overlap for a distance AP, commonly referred to as the “aperture” of the IDT. The center-to-center distance L between the outermost fingers of the IDT 130 is the “length” of the IDT.

In the example of FIG. 1A, the IDT 130 is at the surface of the front side 112 (e.g., the first surface) of the piezoelectric layer 110. However, as discussed below, in other configurations, the IDT 130 may be at the surface of the back side 114 (e.g., the second surface) of the piezoelectric layer 110 or at both the surfaces of the front and back sides 112, 114 of the piezoelectric layer 110, respectively.

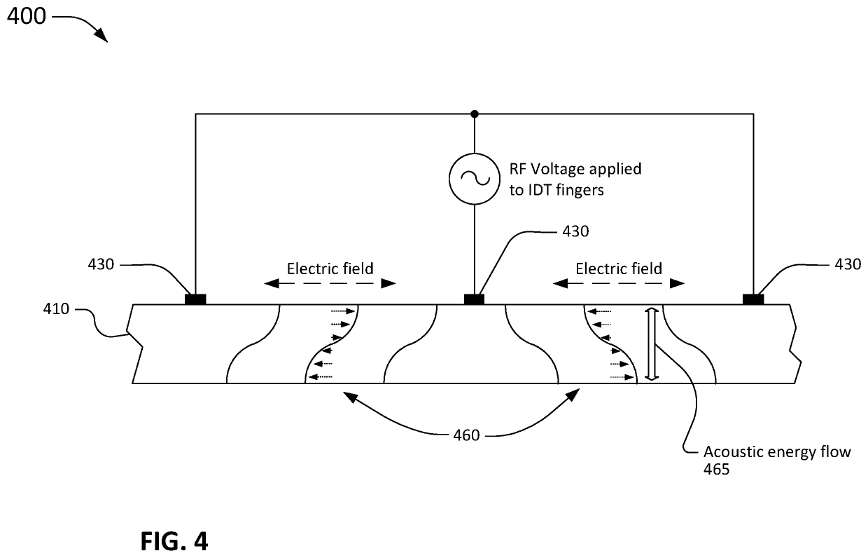

The first and second busbars 132, 134 are configured as the terminals of the XBAR 100. In operation, a radio frequency signal or microwave signal applied between the two busbars 132, 134 of the IDT 130 primarily excites an acoustic mode (i.e., a primarily shear acoustic mode) within the piezoelectric layer 110. As will be discussed in further detail, the primarily excited shear acoustic mode is a bulk shear mode or bulk acoustic wave where acoustic energy of a bulk shear acoustic wave is excited in the piezoelectric layer 110 by the IDT 130 and propagates along a direction substantially and/or primarily orthogonal to the surface of the piezoelectric layer 110, which is also primarily normal, or transverse, to the direction of the electric field created by the IDT fingers. That is, when a radio frequency or a microwave signal is applied between the two busbars 132, 134, the RF voltage applied to the respective sets of IDT fingers generates a time-varying electric field that is laterally excited with respect to a surface of the piezoelectric layer 110. Thus, in some cases the primarily excited acoustic mode may be commonly referred to as a laterally excited bulk acoustic wave since displacement, as opposed to propagation, occurs primarily in the direction of the bulk of the piezoelectric layer, as discussed in more detail below in reference to FIG. 4

For purposes of this disclosure, “primarily acoustic mode” may generally refer to an operational mode in which a vibration displacement is caused in the primarily thickness-shear direction (e.g., X-direction), so the wave propagates substantially and/or primarily in the direction connecting the opposing front and back surfaces of the piezoelectric layer, that is, in the Z direction. In other words, the X-direction component of the wave is significantly smaller than the Z-direction component. The use of the term “primarily” in the “primarily excited acoustic mode” is not necessarily referring to a lower or higher order mode. Thus, the XBAR is considered a transversely excited film bulk wave resonator. One physical constraint is that when the radio frequency or microwave signal is applied between the two busbars 132, 134 of the IDT 130, heat is generated that must be dissipated from the resonator for improved performance. In general, heat can be dissipated by lateral conduction on the membrane (e.g., in the electrodes themselves), and vertical conduction through a cavity to substrate.

In any event, the IDT 130 is positioned at or on the piezoelectric layer 110 such that at least the fingers of the IDT extend at or on the portion of the piezoelectric layer 110 that is over the cavity 140, for example, the diaphragm 115 as described herein. As shown in FIG. 1A, the cavity 140 has a rectangular cross section with an extent greater than the aperture AP and length L of the IDT 130. According to other exemplary aspects, the cavity of an XBAR may have a different cross-sectional shape, such as a regular or irregular polygon. The cavity of an XBAR may have more or fewer than four sides, which may be straight or curved.

According to an exemplary aspect, the area of XBAR 100 is determined as the area of the IDT 130. For example, the area of the IDT 130 can be determined based on the measurement of the length L multiplied by the width of the aperture AP of the interleaved fingers of the IDT 130. As used herein through the disclosure, area is referenced in μm². Thus, the area of the XBAR 100 may be adjusted based on design choices, as described below, thereby adjusting the overall capacitance of the XBAR 100.

For ease of presentation in FIG. 1A, the geometric pitch and width of the IDT fingers is greatly exaggerated with respect to the length (dimension L) and aperture (dimension AP) of the XBAR. A typical XBAR has more than ten parallel fingers in the IDT. For example, an XBAR may have hundreds, possibly thousands, of parallel fingers in the IDT according to exemplary aspects. Similarly, the thickness of the fingers in the cross-sectional views is greatly exaggerated.

FIG. 1B shows a schematic cross-sectional view of an alternative XBAR configuration 100′. In FIG. 1B, the cavity 140 (which can correspond generally to cavity 140 of FIG. 1A) of the resonator 100′ is formed entirely within a dielectric layer 124 (for example SiO₂, as in FIG. 1B) that is located between the substrate 120 (indicated as Si in FIG. 1B) and the piezoelectric layer 110 (indicated as LN in FIG. 1B). Although a single dielectric layer 124 is shown having cavity 140 formed therein (e.g., by etching), it should be appreciated that the dielectric layer 124 can be formed by a plurality of separate dielectric layers formed on each other.

Moreover, in the example of FIG. 1B, the cavity 140 is defined on all sides by the dielectric layer 124. However, in other exemplary embodiments, one or more sides of the cavity 140 may be defined by the substrate 120 or the piezoelectric layer 110. In the example of FIG. 1B, the cavity 140 has a trapezoidal shape. However, as noted above, cavity shape is not limited and may be rectangular, oval, or other shapes.

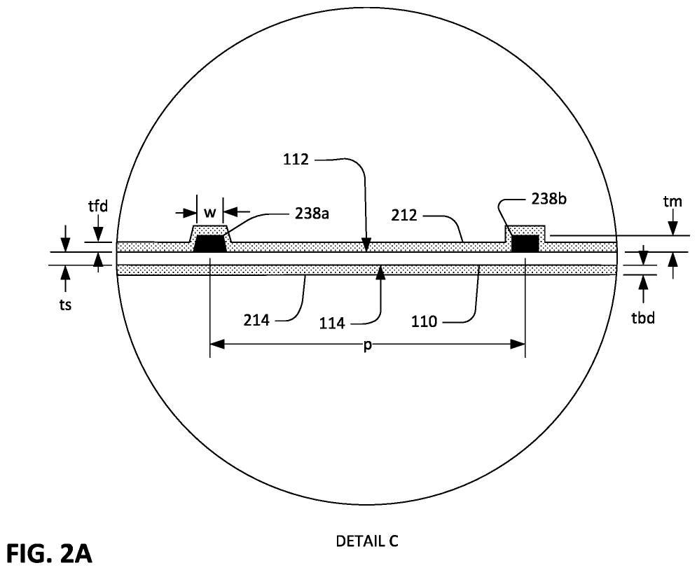

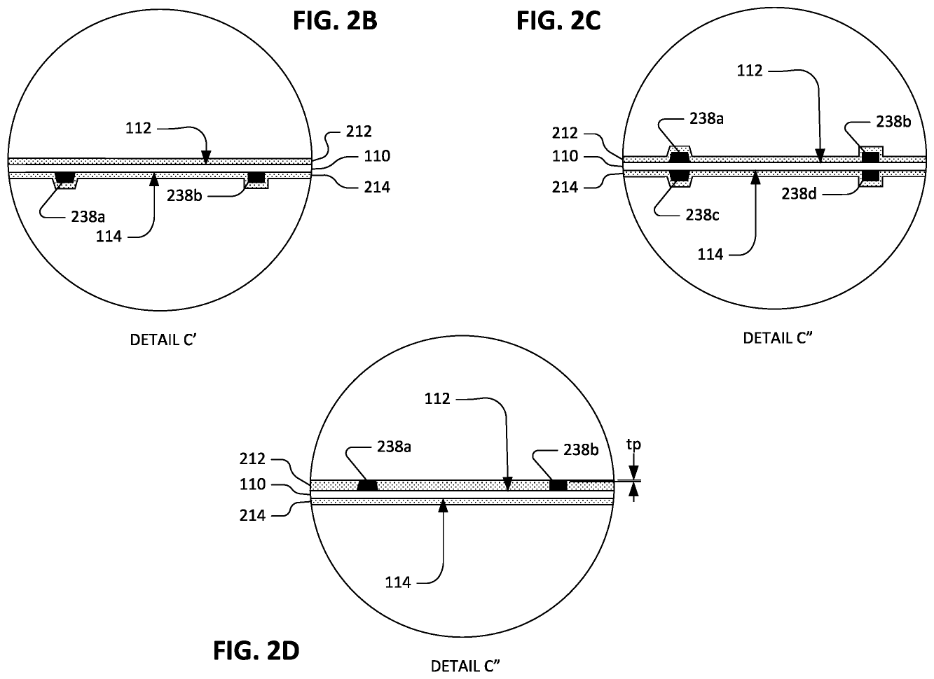

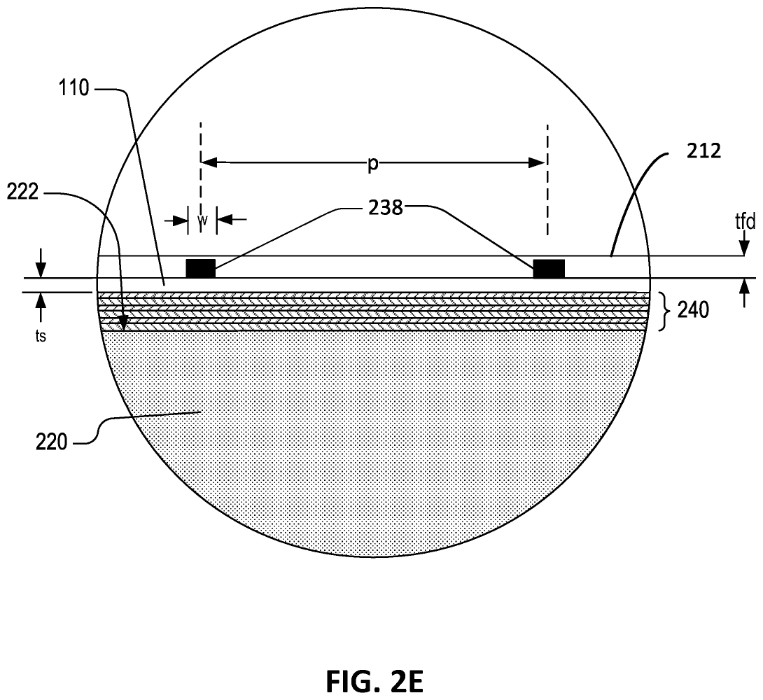

FIG. 2A shows a detailed schematic cross-sectional view of the XBAR 100 of FIG. 1A or 1B. The piezoelectric layer 110 is a single-crystal layer of piezoelectrical material having a thickness ts. ts may be, for example, 100 nm to 1500 nm. When used in filters for 5G NR and Wi-Fi™ bands from 3.4 GHZ to 7 GHZ, the thickness ts may be, for example, 150 nm to 500 nm.

In this aspect, a front side dielectric layer 212 (e.g., a first dielectric coating layer or material) can be formed on the front side 112 of the piezoelectric layer 110. The “front side” of the XBAR is, by definition, the surface facing away from the substrate according to an exemplary aspect. The front side dielectric layer 212 has a thickness tfd. As shown in FIG. 2A the front side dielectric layer 212 covers the IDT fingers 238a, 238b, which can correspond to fingers 136 as described above with respect to FIG. 1A. Although not shown in FIG. 2A, the front side dielectric layer 212 may also be deposited only between the IDT fingers 238a, 238b. In this case, an additional thin dielectric layer (not shown) may be deposited over the IDT fingers to seal and passivate the fingers. Further, although also not shown in FIG. 2A, the front side dielectric layer 212 may also be deposited only on select IDT fingers 238a, for example.

A back side dielectric layer 214 (e.g., a second dielectric coating layer or material) can also be formed on the back side of the back side 114 of the piezoelectric layer 110. In general, for purposes of this disclosure, the term “back side” means on a side opposite the conductor pattern of the IDT structure and/or opposite the front side dielectric layer 212 according to an exemplary aspect. Moreover, the back side dielectric layer 214 has a thickness tbd. The front side and back side dielectric layers 212, 214 may be a non-piezoelectric dielectric material, such as silicon dioxide or silicon nitride. Tfd and tbd may be, for example, 0 to 500 nm. Tfd and tbd may be less than the thickness ts of the piezoelectric layer. Tfd and tbd are not necessarily equal, and the front side and back side dielectric layers 212, 214 are not necessarily the same material. Either or both of the front side and back side dielectric layers 212, 214 may be formed of multiple layers of two or more materials according to various exemplary aspects.

The IDT fingers 238a, 238b may be aluminum, substantially and/or predominantly aluminum alloys, copper, substantially and/or predominantly copper alloys, beryllium, gold, or some other conductive material. Thin (relative to the total thickness of the conductors) layers of other metals, such as chromium or titanium, may be formed under and/or over the fingers to improve adhesion between the fingers and the piezoelectric layer 110 and/or to passivate or encapsulate the fingers. The busbars (132, 134 in FIG. 1A) of the IDT may be made of the same or different materials as the fingers. The cross-sectional shape of the IDT fingers may be trapezoidal (finger 238a), rectangular (finger 238b) or some other shape in various exemplary aspects.

Dimension p (the “pitch”) is the center-to-center spacing between adjacent IDT fingers, such as the IDT fingers 238a, 238b in FIGS. 2A-2C. Center points of center-to-center spacing may be measured at a center of the width “w” of a finger as shown in FIG. 2A. In some cases, the center-to-center spacing may change if the width of a given finger changes along the length of the finger, if the width and extending direction changes, or any variation thereof. In that case, for a given location along AP, center-to-center spacing may be measured as an average center-to-center spacing, a maximum center-to-center spacing, a minimum center-to-center spacing, or any variation thereof. Adjacent fingers may each extend from a different busbar and center-to-center spacing may be measured from a center of a first finger extending from a first busbar to a center of a second finger, adjacent to the first finger, extending from a second busbar. The center-to-center spacing may be constant over the length of the IDT, in which case the dimension p may be referred to as the pitch of the IDT and/or the pitch of the XBAR. However, according to an exemplary aspect as will be discussed in more detail below, the center-to-center spacing varies along the length of the IDT, in which case the pitch of the IDT may be the average value of dimension p over the length of the IDT. Center-to-center spacing from one finger to an adjacent finger may vary continuously when compared to other adjacent fingers, in discrete sections of multiple adjacent pairs, or any combination thereof. Each IDT finger, such as the IDT fingers 238a, 238b in FIGS. 2A, 2B, and 2C, has a width w measured normal to the long direction of each finger. The width w may also be referred to herein as the “mark.” In general, the width of the IDT fingers may be constant over the length of the IDT, in which case the dimension w may be the width of each IDT finger. However, in an exemplary aspect as will be discussed below, the width of individual IDT fingers varies along the length of the IDT 130, in which case dimension w may be the average value of the widths of the IDT fingers over the length of the IDT. Note that the pitch p and the width w of the IDT fingers are measured in a direction parallel to the length L of the IDT, as defined in FIG. 1A.

In general, the IDT of an XBAR differs substantially from the IDTs used in surface acoustic wave (SAW) resonators, primarily in that IDTs of an XBAR excite a shear thickness mode, as described in more detail below with respect to FIG. 4, where SAW resonators excite a surface wave in operation. Moreover, in a SAW resonator, the pitch of the IDT is one-half of the acoustic wavelength at the resonance frequency. Additionally, the mark-to-pitch ratio of a SAW resonator IDT is typically close to 0.5 (i.e., the mark or finger width is about one-fourth of the acoustic wavelength at resonance). In an XBAR, the pitch p of the IDT is typically 2 to 20 times the width w of the fingers. In addition, the pitch p of the IDT is typically 2 to 20 times the thickness ts of the piezoelectric layer 110. Moreover, the width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w, as the lithography process typically cannot support a configuration where the thickness is greater than the width. The thickness of the busbars (132, 134 in FIG. 1A) of the IDT may be the same as, less than, greater than, or any combination thereof, the thickness tm of the IDT fingers. It is noted that the XBAR devices described herein are not limited to the ranges of dimensions described herein.

Moreover, unlike a SAW filter, the resonance frequency of an XBAR is dependent on the total thickness of its diaphragm (i.e., in the vertical or thickness direction), including the piezoelectric layer 110, and the front side and back side dielectric layers 212, 214 disposed thereon. In an exemplary aspect, the thickness of one or both dielectric layers can be varied to change the resonance frequencies of various XBARs in a filter. For example, shunt resonators in a ladder filter circuit may incorporate thicker dielectric layers to reduce the resonance frequencies of the shunt resonators relative to series resonators with thinner dielectric layers, and thus a thinner overall thickness.

Referring back to FIG. 2A, the thickness tfd of the front side dielectric layer 212 over the IDT fingers 238a, 238b may be greater than or equal to a minimum thickness required to deal and passivate the IDT fingers and other conductors on the front side 112 to the piezoelectric layer 110. The minimum thickness may be, for example, 10 nm to 50 nm depending on the material of the front side dielectric layer and method of deposition according to an exemplary aspect. The thickness of the back side dielectric layer 214 may be configured to a specific thickness to adjust the resonance frequency of the resonator as will be described in more detail below.

Although FIG. 2A discloses a configuration in which IDT fingers 238a and 238b are at the front side 112 of the piezoelectric layer 110, alternative configurations can be provided. For example, FIG. 2B shows an alternative configuration in which the IDT fingers 238a, 238b are at the back side 114 of the piezoelectric layer 110 (i.e., facing the cavity) and are covered by a back side dielectric layer 214. A front side dielectric layer 212 may cover the front side 112 of the piezoelectric layer 110. In exemplary aspects, a dielectric layer disposed on the diaphragm of each resonator can be trimmed or etched to adjust the resonant frequency. However, if the dielectric layer is on the side of the diaphragm facing the cavity, there may be a change in spurious modes (e.g., generated by the coating on the fingers). Moreover, with the passivation layer coated on top of the IDTs, the mark changes, which can also cause spurs. Therefore, disposing the IDT fingers 238a, 238b at the back side 114 of the piezoelectric layer 110 as shown in FIG. 2B may eliminate addressing both the change in frequency as well as the effect it has on spurs as compared when the IDT fingers 238a and 238b are on the front side 112 of the piezoelectric layer 110.

FIG. 2C shows an alternative configuration in which IDT fingers 238a, 238b are on the front side 112 of the piezoelectric layer 110 and are covered by a front side dielectric layer 212. IDT fingers 238c, 238d are also on the back side 114 of the piezoelectric layer 110 and are also covered by a back side dielectric layer 214. As previously described, the front side and back side dielectric layer 212, 214 are not necessarily the same thickness or the same material.

FIG. 2D shows another alternative configuration in which IDT fingers 238a, 238b are on the front side 112 of the piezoelectric layer 110 and are covered by a front side dielectric layer 212. The surface of the front side dielectric layer is planarized. The front side dielectric layer may be planarized, for example, by polishing or some other method. A thin layer of dielectric material having a thickness tp may cover the IDT finger 238a, 238b to seal and passivate the fingers. The dimension TP may be, for example, 10 nm to 50 nm.

Each of the XBAR configurations described above with respect to FIGS. 2A to 2D include a diaphragm spanning over a cavity. However, in an alternative aspect, the bulk acoustic resonator can be solidly mounted in which the diaphragm with IDT fingers is mounted on or above a Bragg mirror, which in turn can be mounted on a substrate.

In particular, FIG. 2E shows a detailed schematic cross-sectional view of a solidly mounted XBAR (SM XBAR). The SM XBAR includes a piezoelectric layer 110 and an IDT (of which only two fingers 238 are visible) with a dielectric layer 212 disposed on the piezoelectric layer 110 and IDT fingers 238. The piezoelectric layer 110 has parallel front and back surfaces similar to the configurations described above. Dimension ts is the thickness of the piezoelectric layer 110. The width of the IDT fingers 238 is dimension w, thickness of the IDT fingers is dimension tm, and the IDT pitch is dimension p.

In contrast to the XBAR devices shown in FIG. 1A, the IDT of an SM XBAR in FIG. 2E is not formed on a diaphragm spanning a cavity in the substrate. Instead, an acoustic Bragg reflector 240 is sandwiched between a surface 222 of the substrate 220 and the back surface of the piezoelectric layer 110. The term “sandwiched” means the acoustic Bragg reflector 240 is both disposed between and mechanically attached to a surface 222 of the substrate 220 and the back surface of the piezoelectric layer 110. In some circumstances, layers of additional materials may be disposed between the acoustic Bragg reflector 240 and the surface 222 of the substrate 220 and/or between the Bragg reflector 240 and the back surface of the piezoelectric layer 110. Such additional material layers may be present, for example, to facilitate bonding the piezoelectric layer 110, the acoustic Bragg reflector 240, and the substrate 220.

The acoustic Bragg reflector 240 may be an acoustic mirror configured to reflect at least a portion of the primary acoustic mode excited in the piezoelectric and includes multiple dielectric layers that alternate between materials having high acoustic impedance and materials having low acoustic impedance. The acoustic impedance of a material is the product of the material's shear wave velocity and density. “High” and “low” are relative terms. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. As discussed above, the primary acoustic mode in the piezoelectric layer of an XBAR is a shear bulk wave. In an exemplary aspect, each layer of the acoustic Bragg reflector 240 has a thickness equal to, or about, one-fourth of the wavelength in the layer of a shear bulk wave having the same polarization as the primary acoustic mode at or near a resonance frequency of the SM XBAR. Dielectric materials having comparatively low acoustic impedance include silicon dioxide, carbon-containing silicon oxide, and certain plastics such as cross-linked polyphenylene polymers. Materials having comparatively high acoustic impedance include hafnium oxide, silicon nitride, aluminum nitride, silicon carbide. All of the high acoustic impedance layers of the acoustic Bragg reflector 240 are not necessarily the same material, and all of the low acoustic impedance layers are not necessarily the same material. In the example of FIG. 2E, the acoustic Bragg reflector 240 has a total of six layers, but an acoustic Bragg reflector may have more than, or less than, six layers in alternative configurations.

The IDT fingers, such as IDT finger 238a and 238b, may be disposed on a surface of the front side 112 of the piezoelectric layer 110. Alternatively, IDT fingers, such as IDT finger 238a and 238b, may be disposed in grooves formed in the surface of the front side 112. The grooves may extend partially through the piezoelectric layer. Alternatively, the grooves may extend completely through the piezoelectric layer.

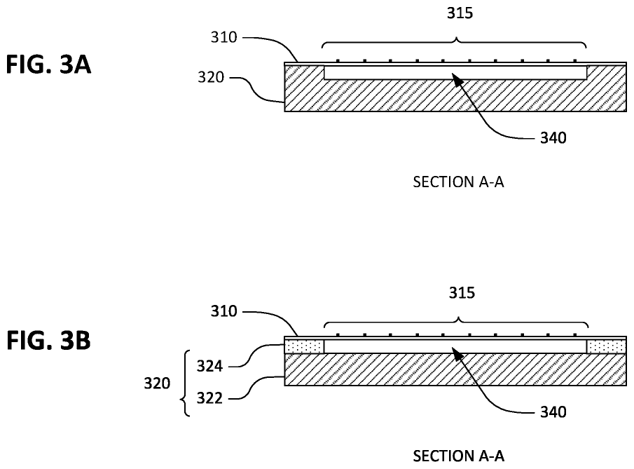

FIG. 3A and FIG. 3B show two exemplary cross-sectional views along the section plane A-A defined in FIG. 1A of XBAR 100. In FIG. 3A, a piezoelectric layer 310, which corresponds to piezoelectric layer 110, is attached directly to a substrate 320, which can correspond to substrate 120 of FIG. 1A. Moreover, a cavity 340, which does not fully penetrate the substrate 320, is formed in the substrate under the portion (i.e., the diaphragm 315) of the piezoelectric layer 310 containing the IDT of an XBAR. The cavity 340 can correspond to cavity 140 of FIGS. 1A and/or 1B in an exemplary aspect. In an exemplary aspect, the cavity 340 may be formed, for example, by etching the substrate 320 before attaching the piezoelectric layer 310. Alternatively, the cavity 340 may be formed by etching the substrate 320 with a selective etchant that reaches the substrate through one or more openings provided in the piezoelectric layer 310.

FIG. 3B illustrates an alternative aspect in which the substrate 320 includes a base 322 and an intermediate layer 324 that is disposed between the piezoelectric layer 310 and the base 322. For example, the base 322 may be silicon (e.g., a silicon support substrate) and the intermediate layer 324 may be silicon dioxide or silicon nitride or some other material, e.g., an intermediate dielectric layer. That is, in this aspect, the base 322 and the intermediate layer 324 are collectively considered the substrate 320. As further shown, cavity 340 is formed in the intermediate layer 324 under the portion (i.e., the diaphragm 315) of the piezoelectric layer 310 containing the IDT fingers of an XBAR. The cavity 340 may be formed, for example, by etching the intermediate layer 324 before attaching the piezoelectric layer 310. Alternatively, the cavity 340 may be formed by etching the intermediate layer 324. In other example embodiments, the cavity 340 may be defined in the intermediate layer 324 by other means from whether the intermediate layer 324 was etched to define the cavity 340. In some cases, the etching may be performed with a selective etchant that reaches the substrate through one or more openings (not shown) provided in the piezoelectric layer 310.

In this case, the diaphragm 315, which can correspond to diaphragm 115 of FIG. 1A, for example, in an exemplary aspect, may be contiguous with the rest of the piezoelectric layer 310 around a large portion of a perimeter of the cavity 340. For example, the diaphragm 315 may be contiguous with the rest of the piezoelectric layer 310 around at least 50% of the perimeter of the cavity 340. As shown in FIG. 3B, the cavity 340 extends completely through the intermediate layer 324. That is, the diaphragm 315 can have an outer edge that faces the piezoelectric layer 310 with at least 50% of the edge surface of the diaphragm 315 coupled to the edge of the piezoelectric layer 310 facing the diaphragm 315. This configuration provides for increased mechanical stability of the resonator.

In other configurations, the cavity 340 may partially extend into, but not entirely through the intermediate layer 324 (i.e., the intermediate layer 324 may extend over the bottom of the cavity on top of the base 322) or may extend through the intermediate layer 324 and into (either partially or wholly) the base 322. As described above, it should be appreciated that the interleaved fingers of the IDT can be disposed on either or both surfaces of the diaphragm 315 in FIGS. 3A and 3B according to various exemplary aspects.

FIG. 4 is a graphical illustration of the primarily excited acoustic mode of interest in an XBAR. FIG. 4 shows a small portion of an XBAR 400 including a piezoelectric layer 410 and three interleaved IDT fingers 430. In general, the exemplary configuration of XBAR 400 can correspond to any of the configurations described above and shown in FIGS. 2A to 2D according to an exemplary aspect. Thus, it should be appreciated that piezoelectric layer 410 can correspond to piezoelectric layer 110 and IDT fingers 430 can be implemented according to any of the configurations of fingers 238a and 238b, for example.

In operation, an RF voltage is applied to the interleaved fingers 430. This voltage creates a time-varying electric field between the fingers. The direction of the electric field is lateral (i.e., laterally excited), or primarily parallel to the surface of the piezoelectric layer 410, as indicated by the arrows labeled “electric field.” Due to the high dielectric constant of the piezoelectric layer 410, the electric field is highly concentrated in the piezoelectric layer relative to the air. The lateral electric field introduces shear deformation in the piezoelectric layer 410, and thus strongly excites a shear acoustic mode, in the piezoelectric layer 410. In this context, “shear deformation” is Defined as deformation in which parallel planes in a material remain parallel and maintain a constant distance while translating relative to each other. In other words, the parallel planes of material are laterally displaced with respect to each other. A “shear acoustic mode” is defined as an acoustic vibration mode in a medium that results in shear deformation of the medium. The shear deformations in the XBAR 400 are represented by the curves 460, with the adjacent small arrows providing a schematic indication of the direction and magnitude of atomic motion. It is noted that the degree of atomic motion, as well as the thickness of the piezoelectric layer 410, have been exaggerated for ease of visualization in FIG. 4. While the atomic motions are predominantly lateral (i.e., horizontal as shown in FIG. 4), the direction of acoustic energy flow of the primarily excited shear acoustic mode is substantially and/or primarily orthogonal to the surface of the piezoelectric layer, as indicated by the arrow 465.

A bulk acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. Thus, high piezoelectric coupling enables the design and implementation of microwave and millimeter-wave filters with appreciable bandwidth.

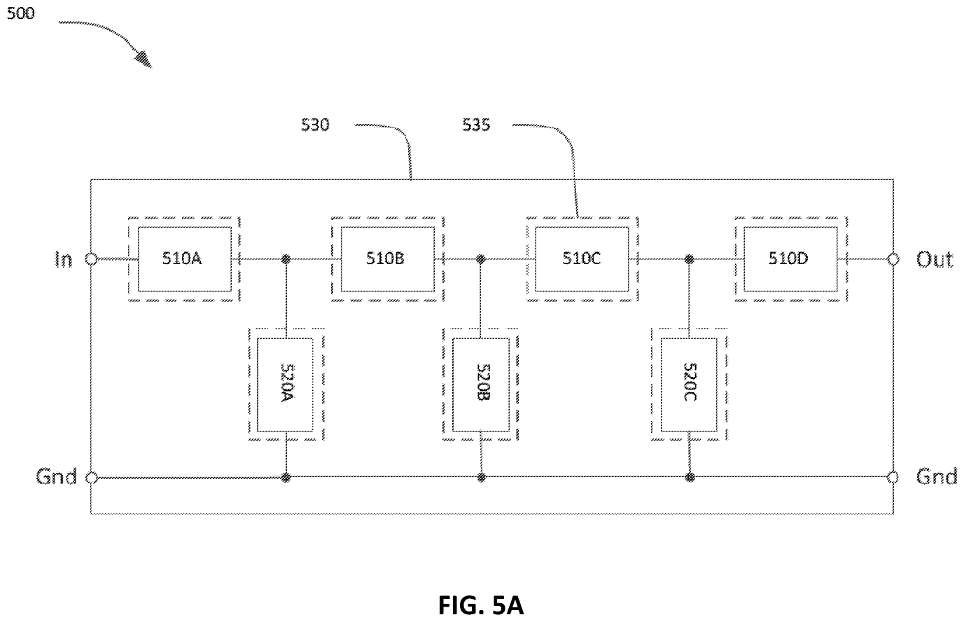

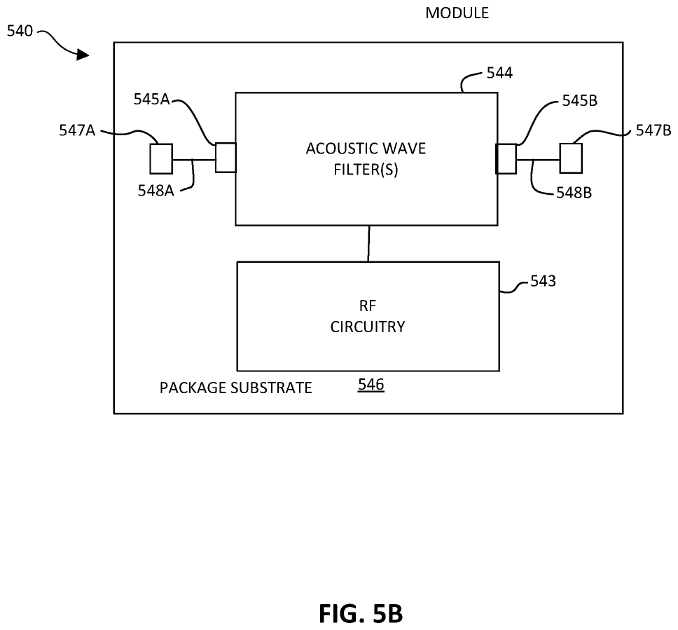

FIG. 5A is a schematic circuit diagram and layout for a high frequency band-pass filter 500 using XBARs, such as the general XBAR configuration 100 described above, for example. The filter 500 has a conventional ladder filter architecture having a plurality of bulk acoustic resonators including four resonators 510A, 510B, 510C, and 510D and three shunt resonators 520A, 520B and 520C. The series resonators 510A, 510B, 510C and 510D are connected in series between a first port and a second port (hence the term “series resonator”). In FIG. 5A, the first and second ports are labeled “In” and “Out”, respectively. However, the filter 500 is bidirectional and either port may serve as the input or output of the filter. At least two shunt resonators, such as the shunt resonators 520A and 520B, are connected from nodes between series resonators to a ground connection. A filter may contain additional reactive components, such as inductors, not shown in FIG. 5A. All the shunt resonators and series resonators are XBARs (e.g., either of the XBAR configurations 100 and/or 100′ as discussed above) in the exemplary aspect. The inclusion of three series and two shunt resonators is an example. A filter may have more or fewer than five total resonators, more or fewer than three series resonators, and more or fewer than two shunt resonators. Typically, all of the series resonators are connected in series between an input and an output of the filter. All of the shunt resonators are typically connected between ground and the input, the output, or a node between two series resonators.

In the exemplary filter 500, the series resonators 510A, 510B, 510C and 510D and the shunt resonators 520A, 520B and 520C of the filter 500 are formed on at least one, and in some cases a single, piezoelectric layer 530 of piezoelectric material bonded to a silicon substrate (not visible). However, in alternative aspects, the individual resonators may each be formed on a separate piezoelectric layer bonded to a separate substrate, for example. Moreover, each resonator includes a respective IDT (not shown), with at least the fingers of the IDT disposed over a cavity, or an acoustic mirror, in the substrate. In this and similar contexts, the term “respective” means “relating things each to each,” which is to say with a one-to-one correspondence. In FIG. 5A, the cavities are illustrated schematically as the dashed rectangles (such as the rectangle 535). In this example, each IDT is disposed over a respective cavity. In other filters, the IDTs of two or more resonators may be disposed over a single cavity.

Each of the resonators 510A, 510B, 510C, 510D, 520A, 520B and 520C in the filter 500 has a resonance where the admittance of the resonator is very high and an anti-resonance where the admittance of the resonator is very low. The resonance and anti-resonance occur at a resonance frequency and an anti-resonance frequency, respectively, which may be the same or different for the various resonators in the filter 500. In simplified terms, each resonator can be considered a short-circuit at its resonance frequency and an open circuit at its anti-resonance frequency. The input-output transfer function will be near zero at the resonance frequencies of the shunt resonators and at the anti-resonance frequencies of the series resonators. In a typical filter, the resonance frequencies of the shunt resonators are positioned below the lower edge of the filter's passband and the anti-resonance frequencies of the series resonators are positioned above the upper edge of the passband.

The frequency range between resonance and anti-resonance frequencies of a resonator corresponds to the coupling of the resonator. Depending on the design parameters of the filter 500, each of the resonators 510A, 510B, 510C, 510D, 520A, 520B and 520C may have a particular coupling parameter to which the respective resonator is tuned in order to achieve the required frequency response of the filter 500.

According to an exemplary aspect, each of the series resonators 510A-510D and the shunt resonators 520A-520C can have an XBAR configuration as described above with respect to FIGS. 1-2D in which a diaphragm with IDT fingers spans over a cavity. Alternatively, each of the series resonators 510A-510D and the shunt resonators 520A-520C can have an XBAR configuration in which the resonators can be solidly mounted on or above a Bragg mirror (e.g., as shown in FIG. 2E), which in turn can be mounted on a substrate.

FIG. 5B is a schematic diagram of a radio frequency module that includes an acoustic wave filter device according to an exemplary aspect. In particular, FIG. 5B illustrate a radio frequency module 540 that includes one or more acoustic wave filters 544 according to an exemplary aspect. The illustrated radio frequency module 540 also includes radio frequency (RF) circuitry (or circuit) 543. In an exemplary aspect, the acoustic wave filters 544 may include one or more of filter 500 including XBARs, as described above with respect to FIG. 5A.

The acoustic wave filter 544 shown in FIG. 5B includes terminals 545A and 545B (e.g., first and second terminals). The terminals 545A and 545B can serve, for example, as an input contact and an output contact for the acoustic wave filter 544. Although two terminals are illustrated, any suitable number of terminals can be implemented for a particular application. The acoustic wave filter 544 and the RF circuitry 543 are on a package substrate 546 (e.g., a common substrate) in FIG. 5B. The package substrate 546 can be a laminate substrate. The terminals 545A and 545B can be electrically connected to contacts 547A and 547B, respectively, on the package substrate 546 by way of electrical connectors 548A and 548B, respectively. The electrical connectors 548A and 548B can be bumps or wire bonds, for example. In an exemplary aspect, the acoustic wave filter 544 and the RF circuitry 543 may be enclosed together within a common package, with or without using the package substrate 546.

The RF circuitry 543 can include any suitable RF circuitry. For example, the RF circuitry can include one or more radio frequency amplifiers (e.g., one or more power amplifiers and/or one or more low noise amplifiers), one or more radio frequency switches, one or more additional RF filters, one or more RF couplers, one or more delay lines, one or more phase shifters, or any suitable combination thereof. The RF circuitry 543 can be electrically connected to the one or more acoustic wave filters 544. The radio frequency module 540 can include one or more packaging structures to, for example, provide protection and/or facilitate easier handling of the radio frequency module 540. Such a packaging structure can include an overmold structure formed over the package substrate 546. The overmold structure can encapsulate some or all of the components of the radio frequency module 540.

According to an exemplary aspect, an RF filter device, such as filter 500 described above with respect to FIG. 5A or the acoustic wave filters 544 described above with respect to FIG. 5B, can be configured to include an additional pole at the UBE to improve the filter device's UBE steepness (also referred to as stiffness). As will be discussed in detail below, a capacitor is connected in shunt with series resonators to provide for the additional pole. Moreover, the additional element (e.g., the capacitor) can have its own resonant frequency, and the combination of the elements can create an additional pole at the upper band edge.

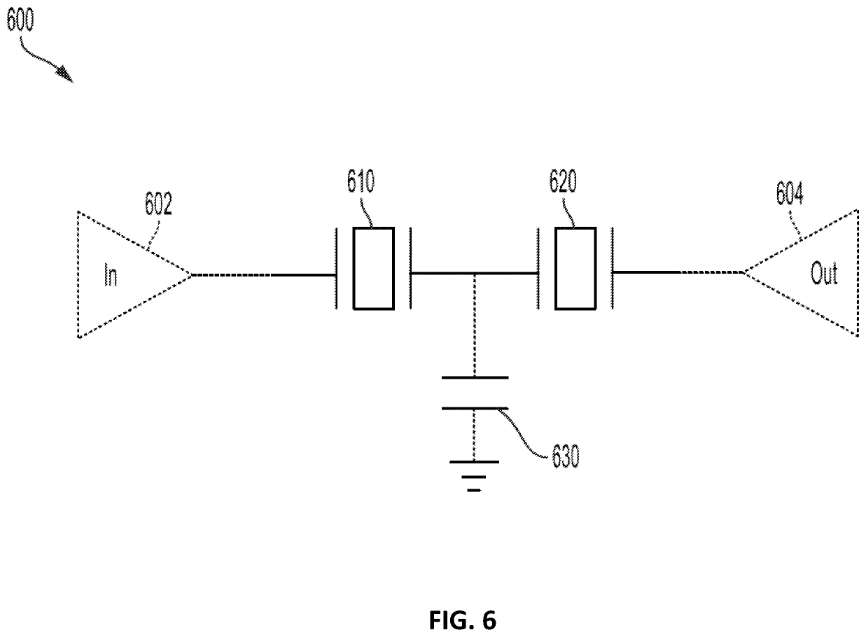

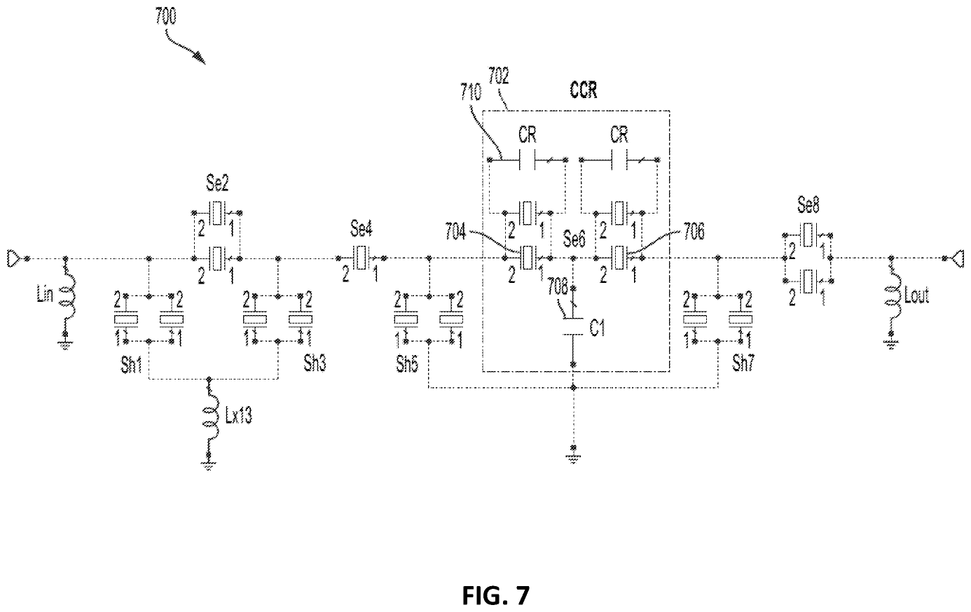

FIG. 6 is a high-level schematic diagram of a filter device 600 including a capacitively-coupled resonator according to an exemplary aspect. As shown, the filter device 600 can include two series resonators 610 and 620 and capacitor 630. The two series resonators 610 and 620 are connected in series between a first port 602 and a second port 604. In FIG. 6, the first and second ports are labeled “In” and “Out”, respectively. However, the filter device 600 can be bidirectional in an exemplary aspect in which either port is configured to serve as the input or output of the filter. As shown, capacitor 630 bisects the series resonators 610, 620 in that it is coupled between ground (e.g., a ground connection) and a node between the pair of series resonators 610 and 620. In this regard, the capacitor 630 is connected in shunt at the node between the series resonators 610, 620 to ground. In some implementations, all the series resonators 610, 620 are XBARs on a single die, for example.

According to the exemplary aspect, the two series resonators 610 and 620 form a capacitively-coupled resonator for filter device 600 and can also be formed on a single layer or plate of piezoelectric material bonded to a silicon substrate (not visible) in an exemplary aspect. Alternatively, the series resonators 610 and 620 can be formed by separate piezoelectric layers or plates. Moreover, the series resonators 610, 620 can have a bonding layer formed on the piezoelectric material. As described above, each resonator will include a respective IDT (not shown), with at least the fingers of the IDT disposed on the piezoelectric layer (e.g., over a cavity) as also described above.

In an exemplary aspect, capacitor 630 can include a first conductor and a second conductor. The first conductor may include a first capacitor terminal and the second conductor may include a second capacitor terminal. The first conductor and the second conductor may each be formed of a metal layer. In an exemplary aspect, the first conductor and the second conductor may be formed on a plate of piezoelectric material or may be formed on a substrate such as a silicon substrate or a dielectric layer such as SiO₂ on a substrate such as silicon. In some implementations, the plate of piezoelectric material may be bonded directly to the silicon substrate. In other implementations, the plate of piezoelectric material may be formed on a dielectric layer, which may be bonded to the silicon substrate. In some implementations, the capacitor 630 may include a floating ground arranged between the dielectric layer and the plate of piezoelectric material. In some implementations, the first conductor and the second conductor may be separated laterally by a gap having a predetermined distance in a range of 10 μm to 20 μm, for example. In some implementations, the plate of piezoelectric material includes an etched region beneath the gap.

FIG. 7 is a detailed schematic diagram of a filter device 700 that includes a capacitively-coupled resonator according to an exemplary aspect. In this aspect, the capacitively-coupled resonator 702 includes two series resonators 704 and 706, capacitor C1 708 and a resonator capacitor CR 710. It should be appreciated that the two series resonators 704 and 706 can correspond to resonators 610 and 620 of FIG. 6 and that capacitor C1 708 can correspond to capacitor 630. Moreover, filter device 700 also includes two ports that can generally correspond to ports 602 and 604 as also described above.

In the exemplary configuration, capacitor C1 708 bisects the series resonators 704, 706. For example, capacitor C1 708 is connected in shunt at a node between the series resonators 704, 706 to ground. As will be described in more detail below, capacitor C1 708 is connected in shunt between ground and one of the bulk acoustic resonators of the plurality of series resonators in the filter deice 700 that has a lowest anti-resonance frequency. In this case, the filter device has four series resonators Se2, Se4, Se6 and Se8 that can generally correspond to resonators 510A, 510B, 510C and 510D of FIG. 5A. Thus, in the exemplary aspect, the capacitively-coupled resonator 702 corresponds to series resonator Se6 and is configured to have the lowest anti-resonance frequency, which can be configured relative to the other series resonators by adjusting the IDT area and/or the IDT pitch as would be appreciated to those skilled in the art. Capacitor C1 708 is then shunted to ground in the exemplary aspect as described below.

According to the exemplary aspect, the capacitively-coupled resonator 702 is formed from a plurality of sub-resonators. That is bulk acoustic resonators 704 and 706 are sub-resonators that in turn can each comprise a pair of sub-resonators that each have a same stack and/or identical IDT configuration as each other. For purposes of this disclosure, the term “stack” as used herein refers to a configuration in the thickness (e.g., Z-axis direction) of the respective resonators and/or sub-resonators. Accordingly, a pair of sub-resonators with the same stack will have the same layers (e.g., piezoelectric, dielectric, substrate), and the like, as described herein. These layers will also have the same thickness, taking into account possible manufacturing variances. As described according to an exemplary aspect, the pair of sub-resonators (e.g., sub-resonators 704 and 706) may therefore have the same stack.

As further shown, each of the sub-resonators 704 and 706 can further be divided into two sub-resonators connected in parallel. According to the exemplary aspect, dividing a resonator into multiple sub-resonators reduces the area of each diaphragm which, in turn, reduces the maximum stress in the diaphragm. Moreover, dividing a resonator into multiple sub-resonators also provides more flexibility in arranging the resonators on a chip and may facilitate removing heat from the diaphragms.

As further shown, resonator capacitors CR (e.g., capacitor 710) may be coupled to at least one of the sub-resonators 704, 706 in order to shift the anti-resonance of the CCR downwards and decreasing the electromechanical coupling of the sub-resonators 704, 706. For example, resonator capacitor 710 is coupled in parallel to acoustic sub-resonator 704. In another exemplary aspect, resonator capacitor 710 may be coupled in series with either or both of the resonators 704, 706 in some implementations, or may be coupled in shunt to the resonators 704, 706 in other implementations. In some aspects, the one or more resonator capacitor(s) 710 has a capacitance greater than capacitor 708. For example, the capacitance value of the resonator capacitor 710 may be approximately 0.529 pF, whereas the capacitance value of the capacitor 708 may be approximately 0.0552 pF. It is reiterated that the finite capacitance values described in the present disclosure are for illustrative purposes, and other capacitance values can be realized without departing from the scope of the present disclosure.

Thus, according to the exemplary aspect shown in FIG. 7, a filter device 700 is provided that includes a first port and a second port; a first bulk acoustic resonator 704 and a second bulk acoustic resonator 706 that are connected in series between the first port and the second port. As also described above with respect to FIGS. 1-3, for example, each of the first and second bulk acoustic resonators 704 and 706 can be an XBAR that includes a piezoelectric layer; and an interdigital transducer (IDT) having a plurality of interleaved fingers at a surface of the piezoelectric layer. As an example shown in FIG. 4, the resonators can be configured in that the piezoelectric layer and the IDT of the resonators are configured such that a radio frequency signal applied to the IDT excites a primary shear acoustic mode in the piezoelectric layer. Moreover, the CCR 702 (i.e., with the lowest anti-resonant frequency) includes a capacitor 708 that connected between ground and a node between the first bulk acoustic resonator 704 and the second bulk acoustic resonator 706.

As also described above, the first bulk acoustic resonator 704 and the second bulk acoustic resonator 706 can be sub-resonators the each also comprise a pair of sub-resonators that each have a same stack as each other. Moreover, a pair of additional capacitors CR (e.g., capacitor 710) can be connected in parallel to the pair of sub-resonators, respectively. In the exemplary aspect, capacitor 708 can have a capacitance in a range of 0.0001 pF to 0.25 (picofarads) pF. Moreover, the pair of additional capacitors CR can each have a capacitance that is greater than the capacitor 708 connected between the ground and the node between the first and second bulk acoustic resonators.

As also described above, the filter device 700 can generally be configured as a filter device such as filter device 500 described above with respect to FIG. 5A. In this example, filter device 700 includes four shunt resonators Sh1, Sh3, Sh5 and Sh7, which are each formed by a pair of sub-resonators. As also shown, each sub-resonator is coupled between node labeled as “1” and “2” for applying a radio signal thereto for exiting the primary shear acoustic mode as described herein. Moreover, filter device 700 can include inductors Lin, Lout and Lx13 according to an exemplary configuration. It should be appreciated that these additional components are shown as an exemplary configuration for the filter device 700 and that alternative configurations and components can be implemented with CCR 702. In either event and importantly, capacitor C1 708 is shunted to increase the UBE steepness of the frequency response for the filter device 700.

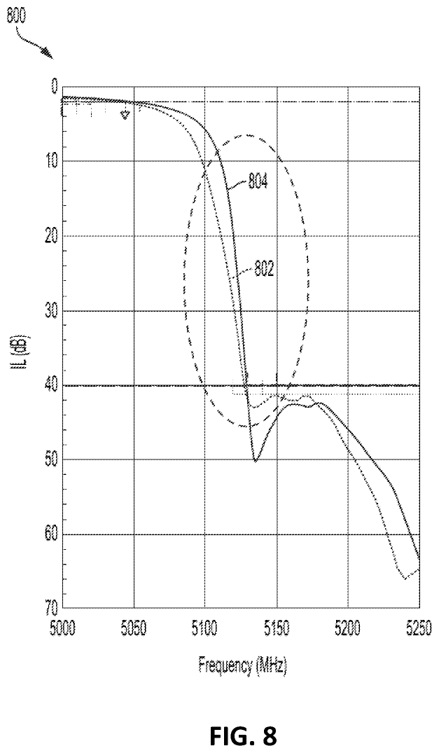

FIG. 8 is an illustration of a graph 800 depicting a frequency response of a capacitively-coupled resonator, such as capacitively-coupled resonator 702 shown in FIG. 7 and described above, for example, which is simulated using finite element method (FEM) simulation techniques. More specifically, the resonance characteristics (e.g., bandpass characteristics) of a bulk acoustic resonator with and without capacitor 708 of the capacitively-coupled resonator 702 are shown in FIG. 8. The frequency response may be in terms of the insertion loss over frequency. As illustrated in FIG. 8, the graph 800 includes a first waveform 802 representing a first frequency response of a bulk acoustic resonator without capacitor 708, and a second waveform 804 representing a second frequency response of the capacitively-coupled resonator (e.g., CCR 702) with capacitor 708.

As illustrated therein, the right-side steepness of the bandpass frequency response may vary between the waveform 802 and the waveform 804. For example, the waveform 804 depicts a sharper steepness than the waveform 802 at the UBE, as indicated by the broken-line elliptical portion in FIG. 8. As a result, graph 800 illustrates the technical advantage of providing the additional pole created at the UBE by the inclusion of the capacitor in the filter design to improve the steepness in the filter response. The pole is provided by adding the capacitor 708 that is shunted to ground for the bulk acoustic resonator (e.g., the resonator that lands at the upper band edge of filter device) that has the lowest anti-resonance frequency of the plurality of bulk acoustic resonators connected in series as described herein. It is reiterated that the relative steepness in the passband of the high edge detrimentally allows for unwanted frequencies to leak or pass through the filter device. Thus, to tune the high edge of the passband, the slope and/or steepness must be increased, i.e., more vertical. According to the exemplary aspect, the increased steepness of the high edge passband (UBE) as shown in FIG. 8 provides for improved effectiveness of the filter device 700, as described above with respect to FIG. 7.

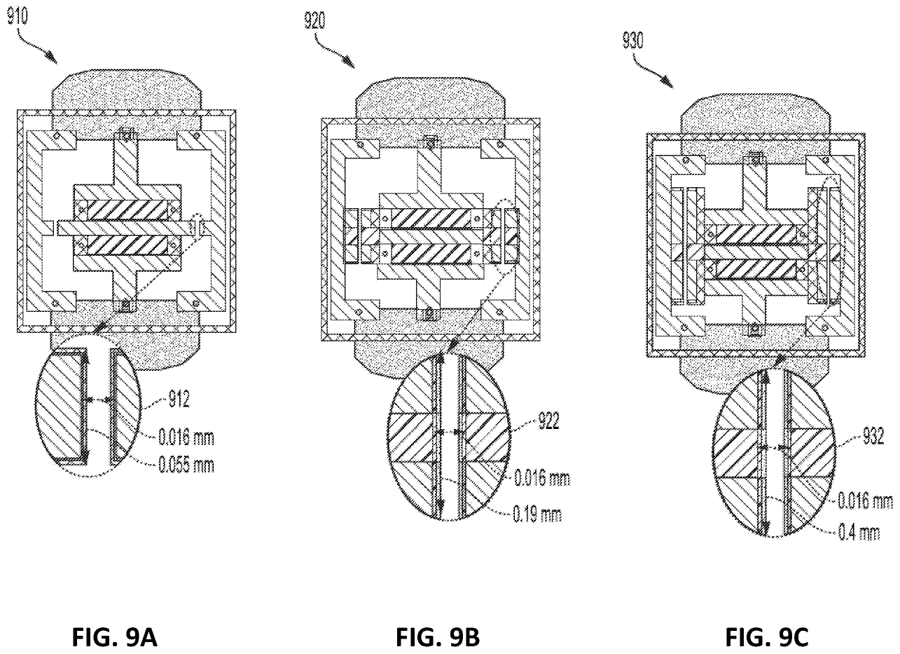

FIGS. 9A to 9C include graphical illustrations of different circuit layouts of a capacitively-coupled resonator. As shown, each of the circuit layouts 910, 920, 930 includes series resonators and a capacitor bisecting the series resonators. In an exemplary aspect, the first circuit layout 910 includes a layout of a capacitor with first and second conductors having a first length. In an example, the first length of the first and second conductors may be about 55 μm with a fixed gap distance of about 16 μm, as indicated by the elliptical portion 912 of FIG. 9A. Moreover, the second circuit layout 920 of FIG. 9B includes a layout of a shunt capacitor with first and second conductors having a second length. In an example, the second length of the first and second conductors may be about 190 μm with a fixed gap distance of about 16 μm, as indicated by the elliptical portion 922 of FIG. 9B. Yet further, the third circuit layout 930 of FIG. 9C includes a layout of a shunt capacitor with first and second conductors having a third length. In an example, the third length of the first and second conductors may be about 400 μm with a fixed gap distance of about 16 μm, as indicated by the elliptical portion 932 of FIG. 9C. In this regard, the first conductor and the second conductor may have lengths in a range of 55 μm to 400 μm. The first conductor and the second conductor may have the same lengths in some implementations, or may have different lengths in other implementations. In some aspects, the capacitance value of the capacitor may be calculated using commercially available FEM software as would be appreciated to one skilled in the art. In some aspects, the gap distance may be in a range of 10 μm to 20 μm. In this regard, the increase in the length dimension as shown between the circuit layouts 910, 920, 930 realizes an increase in the capacitance value. For example, the circuit layout 910 having the shunt capacitor with a metal length of about 55 μm may realize a capacitance value of about 0.0001 pF, whereas the circuit layout 930 having the capacitor with a metal length of about 400 μm may realize a capacitance value of about 0.00243 pF. Therefore, in some example implementations the shunt capacitor 708 of FIG. 7 may have a capacitance in a range of 0.0001 pF to 0.25 pF.

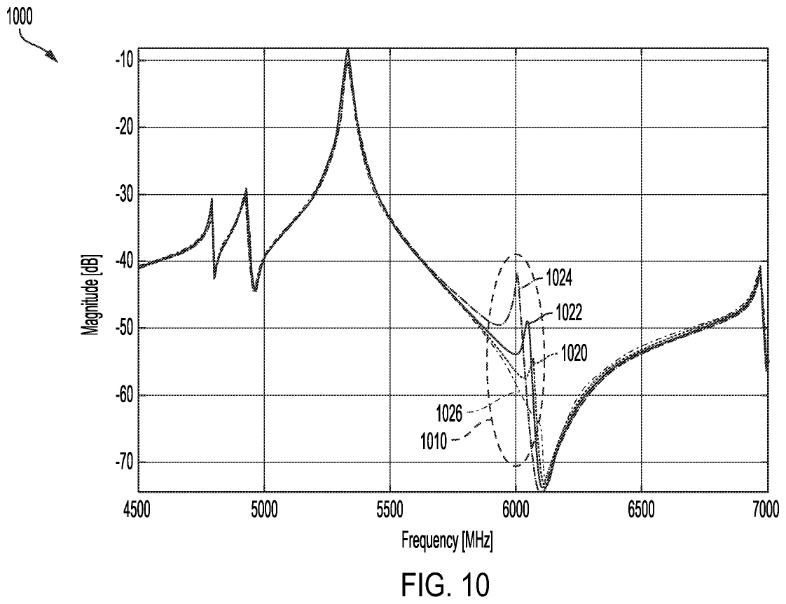

FIG. 10 is a graphical illustration of waveforms depicting a frequency response for each circuit layout of FIGS. 9A to 9C, respectively, and also compared with a similar resonator structure except without the shunt capacitor. More specifically, Magnitude (dB) showing the resonance characteristics (i.e., bandpass characteristics) of the capacitively-coupled resonators of FIGS. 9A to 9C are shown in FIG. 10, which is simulated using finite element method (FEM) simulation techniques. The frequency response is shown in terms of the insertion loss (dB) over frequency (MHz).

As illustrated in FIG. 10, a graph 1000 includes a first waveform 1020 representing a first frequency response of a capacitively-coupled resonator (as indicated by the first circuit layout 910 of FIG. 9A), a second waveform 1022 representing a second frequency response of a capacitively-coupled resonator (as indicated by the second circuit layout 920 of FIG. 9B), and a third waveform 1024 representing a third frequency response of the capacitively-coupled resonator (as indicated by the third circuit layout 930 of FIG. 9C). Moreover, these three waveforms 1020, 1022 and 1024 are compared with waveform 1026, which illustrates a resonator structure without any shunt capacitor, i.e., it is not capacitively coupled. As shown, the right-side steepness of the bandpass frequency response may vary between the waveforms 1020, 1022, 1024. For example, the waveform 1022 depicts a sharper steepness than the waveform 1020 at the UBE, and the waveform 1024 depicts a sharper steepness than the waveform 1022 at the UBE based on an increase in capacitance of the capacitor from about 0.0001 pF (corresponding to waveform 1020) to about 0.00243 pF (corresponding to waveform 1024). This increase in the sharpness of the steepness at the UBE may be due to the pole created at the UBE, as indicated by the broken-line elliptical portion in FIG. 10, by the inclusion of the capacitor with increasing capacitance in the filter design (e.g., 1010) to improve the steepness in the filter response without increasing the number of stages or die size of the overall filter. As shown, waveform 1024 has the largest pole that is due to the third length of the first and second conductors, which is about 400 μm as shown in FIG. 9C. In contrast, waveform 1026 does not have any pole due to the fact that there is no shunt capacitor. As a result, the UBE of this resonator structure has a lower steepness than the three circuit layouts 910, 920, 930 of the respective capacitively-coupled resonators shown in FIGS. 9A to 9C.

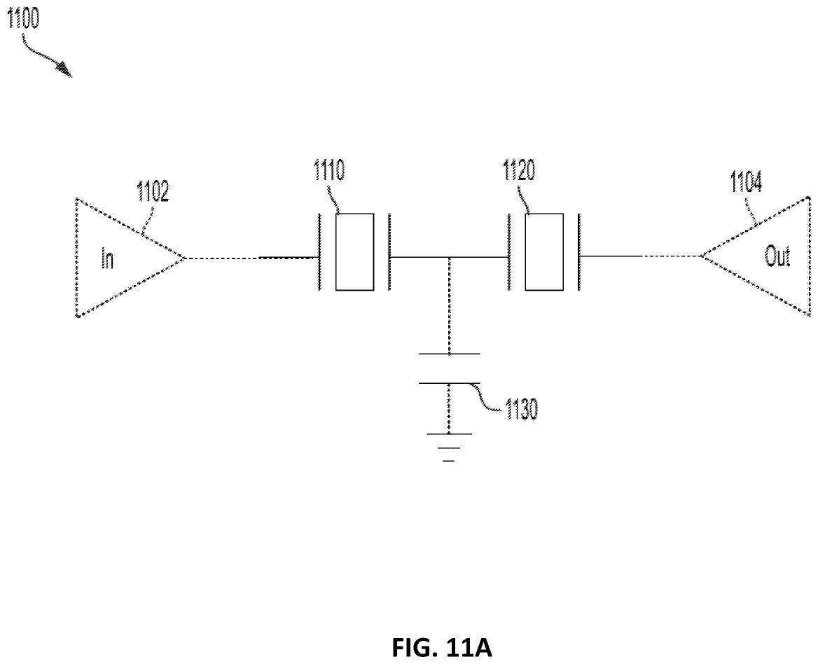

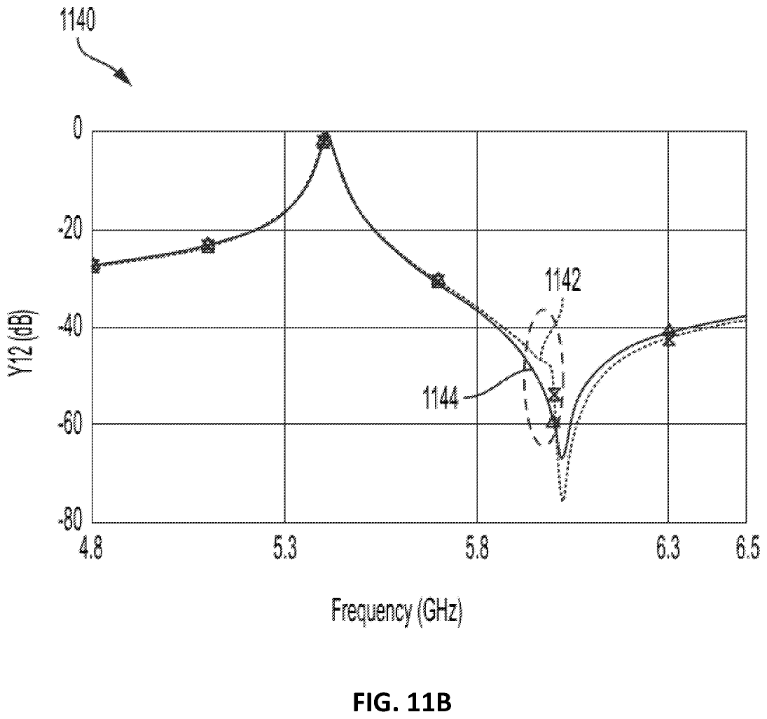

FIG. 11A is another high-level schematic diagram of a filter device 1100 including a capacitively-coupled resonator according to an exemplary aspect. As shown, filter device 1100 comprises a similar configuration as filter device 600 of FIG. 6. That is filter device 110 includes two series resonators 1110 and 1120 and a capacitor 1130. The primary different in this exemplary aspect is that capacitor 1130 is an interdigital capacitor (IDC), which can be a multi-finger periodic structure that uses the capacitance that occurs across a narrow gap between conducting fingers, as described below.

The details of filter device 1100 can correspond to those described above and will not be repeated herein. However, as shown in FIG. 11A, the two series resonators 1110 and 1120 are connected in series between a first port 1102 and a second port 1104. In FIG. 11A, the first and second ports are labeled “In” and “Out”, respectively. Moreover, the IDC 1130 bisects the series resonators 1110, 1120. For example, the IDC 1130 is connected in shunt at a node between the series resonators 1110, 1120 to ground. In some implementations, all the series resonators 1110, 1120 are XBARs on a single die and in one aspect, can be a pair (or pairs) of sub-resonators. Moreover, the IDC 1130 can be provided on the same die as series resonators 1110, 1120 or a separate die. In either configuration, the capacitively-coupled resonator circuit 1100 is configured such that interdigitated capacitive fingers of the IDC 1130 are orthogonal (i.e., extend in a direction perpendicular to) to the interdigitated resonator fingers (e.g., fingers 136 of FIG. 1) of the resonators 1110, 1120. The arrangement configures the capacitively-coupled resonator circuit to avoid excitation of acoustic waves by the structure of the IDC 1130, for example.

It is noted that other forms of capacitors, for example, an edge capacitor, as described above, are larger in size thereby limiting the maximum capacitor value in the overall design of a capacitively-coupled resonator based on size constraints. On the contrary, IDCs are smaller than an edge capacitor thereby reducing the overall filter area. The additional remaining area thereby allows for an increase in the number of stages/resonators. As further described below, the use of the IDC provides for an increase in the overall filter response and edge steepness.

FIG. 11B is a graphical illustration of waveforms depicting a frequency response for the circuit layout of the filter device of FIG. 11A compared to an implementation without the capacitively-coupled resonator. More specifically, in dB showing the resonance characteristics (i.e., bandpass characteristics) of the capacitively-coupled resonator of FIG. 11A, which is simulated using finite element method (FEM) simulation techniques. The frequency response is shown in terms of the insertion loss (dB) over frequency (MHz). As illustrated in FIG. 11B, a graph 1140 includes a first waveform 1142 representing a first frequency response of a capacitively-coupled resonator (as indicated by the capacitively-coupled resonator circuit 1100 of FIG. 11A), and a second waveform 1144 representing a second frequency response of circuit without a capacitively-coupled resonator. The right-side (e.g., upper side) steepness of the bandpass frequency response may vary between the waveforms 1142 and 1144. For example, the waveform 1142 illustrates a sharper (i.e., more vertical) steepness than the waveform 1144 at the UBE. This increase in the sharpness of the steepness at the UBE may be due to an additional pole created at the UBE, as indicated by the broken-line elliptical portion in FIG. 11B, by the inclusion of the capacitor with increasing capacitance in the filter design to improve the steepness in the filter response.

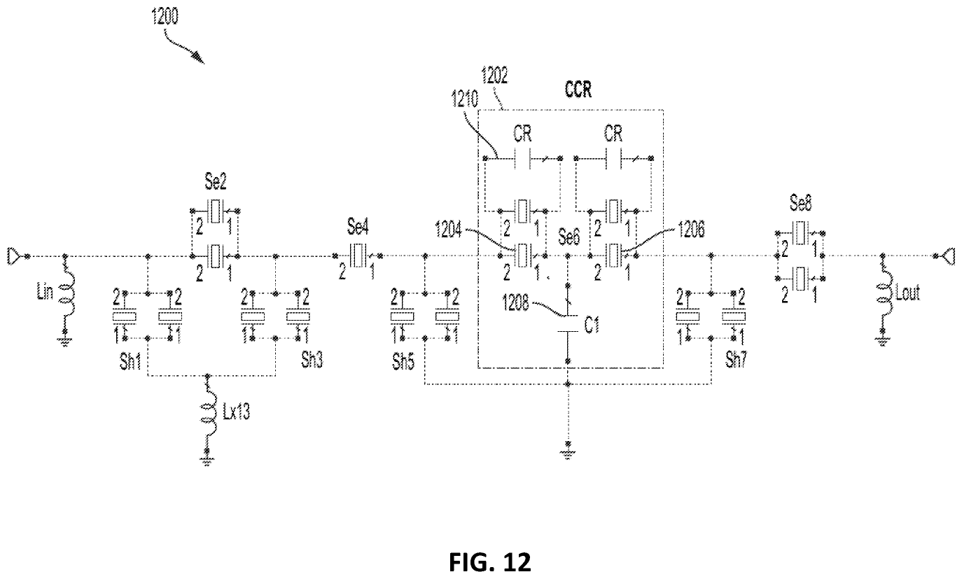

FIG. 12 is another high-level schematic diagram of a filter device 1200 including an IDC C1 1208 included with the capacitively-coupled resonator 1202 according to an exemplary aspect. That is, the capacitively-coupled resonator 1202 includes two series resonators 1204 and 1206 (which can be two or more sub-resonators having the same stack and/or formed on a same die) and an IDC C1 1208. In the exemplary configuration, the IDC C1 1208 bisects the series resonators 1204, 1206. For example, the IDC C1 1208 is connected in shunt at a node between a node between the series resonators 1204, 1206 and ground (i.e., a ground connection). One or more resonator capacitor(s) CR 1210 can be coupled to at least one of the two series resonators 1204, 1206 in an exemplary aspect. The details of these additional configurations are described above with respect to FIG. 7 and will not be repeated herein. That is, the primary difference in this configuration of filter device 1200 is that capacitor C1 1208 is an IDC, which can have a capacitance of approximately 0.12 pF according to an exemplary aspect. It is also reiterated that the finite capacitance values described in the present disclosure are for illustrative purposes, and other capacitance values can be realized without departing from the scope of the present disclosure.

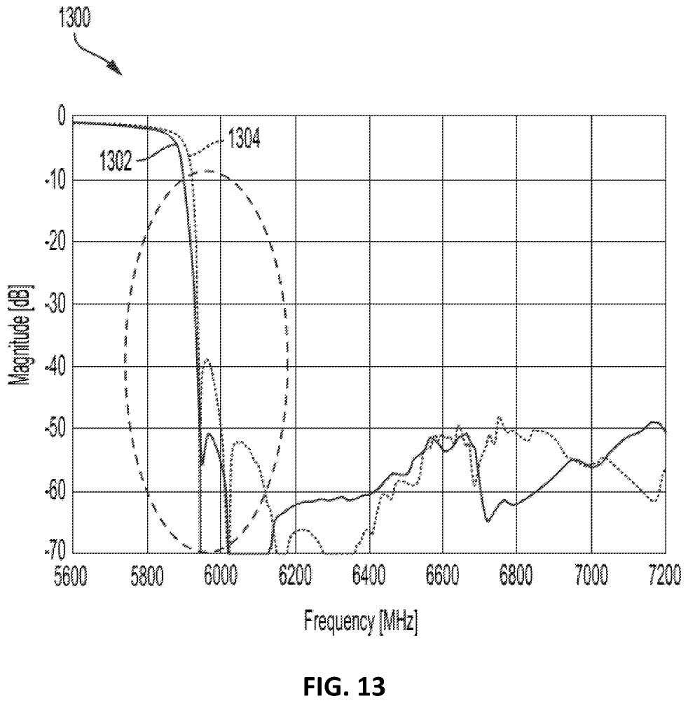

FIG. 13 is an illustration of a graph 1300 depicting a frequency response of a capacitively-coupled resonator 1202 as shown in FIG. 12. The plots of graph 1300 of FIG. 13 can be simulated using finite element method (FEM) simulation techniques. More specifically, the resonance admittance characteristics (i.e., bandpass characteristics) of a bulk acoustic resonator with and without the IDC C1 1208 are shown in FIG. 13. The frequency response may be in terms of the insertion loss over frequency. As illustrated in FIG. 13, the graph 1300 includes a first waveform 1302 representing a first frequency response of an bulk acoustic resonator without a IDC, and a second waveform 1304 representing a second frequency response of the capacitively-coupled resonator with the IDC capacitor (e.g., capacitor C1 1208 of FIG. 12) according to the exemplary aspect as described above. As further shown, the right-side steepness of the bandpass frequency response may vary between the waveform 1302 and the waveform 1304. For example, the waveform 1304 depicts a sharper steepness than the waveform 1302 at the UBE, as indicated by the broken-line elliptical portion in FIG. 13, as this may be due to an additional pole created at the UBE by the inclusion of the IDC in the filter design to improve the steepness in the filter response. Specifically, FIG. 13 illustrates an improvement of high-side filter steepness from 0.47 dB/MHz to 0.63 dB/MHz. where steepness is calculated from 2.5 dB to 50 dB.

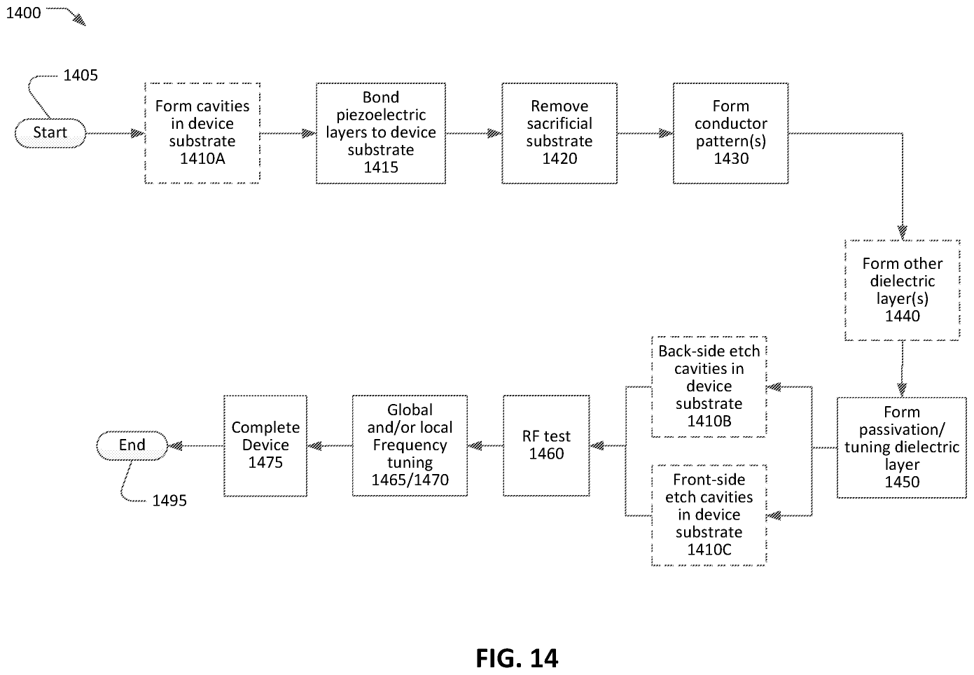

FIG. 14 is a simplified flow chart summarizing a process 1400 for manufacturing a filter device incorporating XBARs according to an exemplary aspect. It should be appreciated that while FIG. 14 generally describes a process for fabricating a single filter device, multiple filter devices may be fabricated simultaneously on a common wafer (consisting of a piezoelectric layer bonded to a substrate). In this case, each step of the process 1400 may be performed concurrently on all of the filter devices on the wafer.

As shown, the process 1400 is for fabricating a filter device including multiple XBARS, such as filter 600, 700, 1100 and/or 1200 as described above. The process 1400 starts at 1405 with a device substrate and a thin layer of piezoelectric material disposed on a sacrificial substrate. The process 1400 ends at 1495 with a completed filter device. It is noted that the flow chart of FIG. 14 includes only major process steps. Various conventional process steps (e.g., surface preparation, cleaning, inspection, baking, annealing, monitoring, testing, etc.) may be performed before, between, after, and during the steps shown in FIG. 14.

The flow chart of FIG. 14 captures three variations of the process 1400 for making an XBAR which differ in whether and how cavities are formed in the device substrate. The cavities may be formed at steps 1410A, 1410B, or 1410C or not at all. It should be appreciated that only one or none of steps 1410A, 1410B, and 1410C is performed in each of the three variations of the process 1400. In order to produce an SM XBAR having Bragg stack layer thicknesses determined according to the present disclosure, a solidly mounted XBAR may be fabricated without forming any cavities in the device substrate. An example of a solidly mounted XBAR was described above with reference to FIG. 2E.

The piezoelectric layer may be, for example, a lithium niobate plate or a lithium tantalate plate, either of which may be Z-cut, rotated Z-cut, Y-cut, rotated Y-cut, or rotated YX-cut. For historical reasons, a rotated Y-cut plate configuration may be commonly referred to as “Y-cut”, where the “cut angle” is the angle between the y axis and the normal to the plate. The “cut angle” is equal to β+90°. For example, a plate with Euler angles [0°, 30°, 0° ] is commonly referred to as “120° rotated Y-cut”. In some embodiments, the piezoelectric layer's z axis may be normal to the plate surface and the y axis orthogonal to the IDT fingers. Such piezoelectric plates have Euler angles of 0, 0, 90°. Further embodiments may include a piezoelectric layer with Euler angles 0, β, 90°, where β is in the range from −15° to +5°, 0°≤β≤60, or any combination thereof. The piezoelectric layer may be some other material and/or some other cut. The device substrate may preferably be silicon. The device substrate may be some other material that allows formation of deep cavities by etching or other processing.

In one variation of the process 1400, one or more cavities are formed in the device substrate at 1410A, before the piezoelectric layer is bonded to the substrate at 1415. A separate cavity may be formed for each resonator in a filter device. The one or more cavities may be formed using conventional photolithographic and etching techniques. Typically, the cavities formed at 1410A will not penetrate through the device substrate. As described above, the cavities may be in a base, such as silicon, of the substrate. Alternatively, the cavities may be in an intermediate layer, such as silicon dioxide, of the substrate.

At 1415, the piezoelectric layer is bonded to the device substrate. The piezoelectric layer and the device substrate may be bonded by a wafer bonding process. Typically, the mating surfaces of the device substrate and the piezoelectric layer are highly polished. One or more layers of intermediate materials, such as an oxide or metal, may be formed or deposited on the mating surface of one or both of the piezoelectric layer and the device substrate. For example, high acoustic impedance and low acoustic impedance layers of the Bragg stack may be formed or deposited on the mating surface or one or both of the piezoelectric layer and device substrate. One or both mating surfaces may be activated using, for example, a plasma process. The mating surfaces may then be pressed together with considerable force to establish molecular bonds between the piezoelectric layer and the device substrate or intermediate material layers.

At 1420, the sacrificial substrate may be removed. For example, the piezoelectric layer and the sacrificial substrate may be a wafer of piezoelectric material that has been ion implanted to create defects in the crystal structure along a plane that defines a boundary between what will become the piezoelectric layer and the sacrificial substrate. At 1420, the wafer may be split along the defect plane, for example by thermal shock, detaching the sacrificial substrate and leaving the piezoelectric layer bonded to the device substrate. The exposed surface of the piezoelectric layer may be polished or processed in some manner after the sacrificial substrate is detached.

Thin layers of single-crystal piezoelectric materials laminated to a non-piezoelectric substrate are commercially available. At the time of this application, both lithium niobate and lithium tantalate layers are available bonded to various substrates including silicon, quartz, and fused silica. Thin layers of other piezoelectric materials may be available now or in the future. The thickness of the piezoelectric layer may be between 300 nm and 1000 nm. When the substrate is silicon, a layer of SiO₂ may be disposed between the piezoelectric layer and the substrate. When a commercially available piezoelectric layer/device substrate laminate is used, steps 1410A, 1415, and 1420 of the process 1400 are not performed in an exemplary aspect.

A first conductor pattern, including IDTs of each XBAR, is formed at 1430 by depositing and patterning one or more conductor layers on the front side of the piezoelectric layer (e.g., piezoelectric layer 110 as described above). The conductor layer may be, for example, aluminum, an aluminum alloy, copper, a copper alloy, or some other conductive metal. One or more layers of other materials may be disposed below (i.e., between the conductor layer and the piezoelectric layer) and/or on top of the conductor layer. For example, a thin film of titanium, chrome, or other metal may be used to improve the adhesion between the conductor layer and the piezoelectric layer. A second conductor pattern of gold, aluminum, copper or other higher conductivity metal may be formed over portions of the first conductor pattern (for example the IDT bus bars and interconnections between the IDTs).

Moreover, each conductor pattern may be formed at 1430 by depositing the conductor layer and, optionally, one or more other metal layers in sequence over the surface of the piezoelectric layer. The excess metal may then be removed by etching through patterned photoresist. The conductor layer can be etched, for example, by plasma etching, reactive ion etching, wet chemical etching, or other etching techniques.

Alternatively, each conductor pattern may be formed at 1430 using a lift-off process. Photoresist may be deposited over the piezoelectric layer. and patterned to define the conductor pattern. The conductor layer and, optionally, one or more other layers may be deposited in sequence over the surface of the piezoelectric layer. The photoresist may then be removed, which removes the excess material, leaving the conductor pattern. In either case, the conductor pattern can be formed to include the grating elements as described herein.

At 1440, one or more frequency setting dielectric layer(s) may be formed by depositing one or more layers of dielectric material on the front side of the piezoelectric layer. For example, a dielectric layer may be formed over the shunt resonators to lower the frequencies of the shunt resonators relative to the frequencies of the series resonators. The one or more dielectric layers may be deposited using a conventional deposition technique such as physical vapor deposition, atomic layer deposition, chemical vapor deposition, or some other method. One or more lithography processes (using photomasks) may be used to limit the deposition of the dielectric layers to selected areas of the piezoelectric layer. For example, a mask may be used to limit a dielectric layer to cover only the shunt resonators.

At 1450, a passivation/tuning dielectric layer may be deposited over the piezoelectric layer and conductor patterns. The passivation/tuning dielectric layer may cover the entire surface of the filter except for pads for electrical connections to circuitry external to the filter. In some instantiations of the process 1400, the passivation/tuning dielectric layer may be formed after the cavities in the base of the device substrate and/or intermediate layer of the substrate are etched at either 1410B or 1410C.

More particularly, in a second variation of the process 1400, one or more cavities are formed in the back surface of the base of the device substrate and/or the intermediate layer of the substrate at 1410B. A separate cavity may be formed for each resonator in a filter device. The one or more cavities may be formed using an anisotropic or orientation-dependent dry or wet etch to open holes through the back side of the device substrate to the piezoelectric layer. In this case, the resulting resonator devices will have a cross-section as shown in FIG. 1A or 1B.

In a third variation of the process 1400, one or more cavities in the form of recesses in the device substrate may be formed at 1410C by etching the substrate using an etchant introduced through openings in the piezoelectric layer. A separate cavity may be formed for each resonator in a filter device. The one or more cavities formed at 1410C will not penetrate through the device substrate.

Ideally, most or all of the filter devices on a wafer will meet a set of performance requirements. However, normal process tolerances will result in variations in parameters such as the thicknesses of dielectric layer formed at 1440 and 1450, variations in the thickness and line widths of conductors and IDT fingers formed at 1430, and variations in the thickness of the piezoelectric layer. These variations contribute to deviations of the filter device performance from the set of performance requirements.

To improve the yield of filter devices meeting the performance requirements, frequency tuning may be performed by selectively adjusting the thickness of the passivation/tuning layer deposited over the resonators at 1450. The frequency of a filter device passband can be lowered by adding material to the passivation/tuning layer, and the frequency of the filter device passband can be increased by removing material to the passivation/tuning layer. Typically, the process 1400 is biased to produce filter devices with passbands that are initially lower than a required frequency range but can be tuned to the desired frequency range by removing material from the surface of the passivation/tuning layer.

At 1460, a probe card or other means may be used to make electrical connections with the filter to allow radio frequency (RF) tests and measurements of filter characteristics such as input-output transfer function. Typically, RF measurements are made on all, or a large portion, of the filter devices fabricated simultaneously on a common piezoelectric layer and substrate.

At 1465, global frequency tuning may be performed by removing material from the surface of the passivation/tuning layer using a selective material removal tool such as, for example, a scanning ion mill as previously described. “Global” tuning is performed with a spatial resolution equal to or larger than an individual filter device. The objective of global tuning is to move the passband of each filter device towards a desired frequency range. The test results from 1460 may be processed to generate a global contour map indicating the amount of material to be removed as a function of two-dimensional position on the wafer. The material is then removed in accordance with the contour map using the selective material removal tool.

At 1470, local frequency tuning may be performed in addition to, or instead of, the global frequency tuning performed at 1465. “Local” frequency tuning is performed with a spatial resolution smaller than an individual filter device. The test results from 1460 may be processed to generate a map indicating the amount of material to be removed at each filter device. Local frequency tuning may require the use of a mask to restrict the size of the areas from which material is removed. For example, a first mask may be used to restrict tuning to only shunt resonators, and a second mask may be subsequently used to restrict tuning to only series resonators (or vice versa). This would allow independent tuning of the lower band edge (by tuning shunt resonators) and upper band edge (by tuning series resonators) of the filter devices.

After frequency tuning at 1465 and/or 1470, the filter device is completed at 1475. Actions that may occur at 1475 include forming forming/coupling the capacitor for the CCR of the resonator (e.g., capacitor C1) to a shunt connection as described above, forming a staggered inductance configuration, forming bonding pads or solder bumps or other means for making connection between the device and external circuitry (if such pads were not formed at 1430); excising individual filter devices from a wafer containing multiple filter devices; other packaging steps; and additional testing. After each filter device is completed, the process ends at 1495.

In general, it is noted that throughout this description, the embodiments and examples shown should be considered as exemplars, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, the pair of terms “top” and “bottom” can be interchanged with the pair “front” and “back”. As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

What is claimed:

1. A filter device comprising:
a first port and a second port;
a first bulk acoustic resonator and a second bulk acoustic resonator connected in series between the first port and the second port, each of the first and second bulk acoustic resonators comprising:
a piezoelectric layer; and
an interdigital transducer (IDT) having a plurality of interleaved fingers at a surface of the piezoelectric layer,
wherein the piezoelectric layer and the IDT are configured such that a radio frequency signal applied to the IDT excites a primary shear acoustic mode in the piezoelectric layer; and
a capacitor connected between ground and a node between the first bulk acoustic resonator and the second bulk acoustic resonator.

2. The filter device according to claim 1, wherein each of the first bulk acoustic resonator and the second bulk acoustic resonator comprises a pair of sub-resonators that each have a same stack as each other.

3. The filter device according to claim 2, further comprising a pair of additional capacitors that are connected in parallel to the pair of sub-resonators, respectively.

4. The filter device according to claim 3, wherein the pair of additional capacitors each have a capacitance greater than the capacitor connected between the ground and the node between the first and second bulk acoustic resonators.

5. The filter device according to claim 1, wherein the capacitor has a capacitance in a range of 0.0001 pF to 0.25 pF.

6. The filter device according to claim 1, wherein the capacitor is connected in shunt with the first and second bulk acoustic resonators.

7. The filter device according to claim 1, wherein the capacitor has a first conductor and a second conductor with the first conductor and the second conductor being separated by a gap having a distance in a range of 10 μm to 20 μm.

8. The filter device according to claim 7, wherein at least a portion of the first conductor and at least a portion of the second conductor are disposed on a piezoelectric layer, wherein the piezoelectric layer includes an etched region beneath the gap.

9. The filter device according to claim 1, wherein the capacitor is an interdigital capacitor comprising a plurality of interdigitated capacitive fingers that extend in a direction substantially orthogonal to a direction of the plurality of interleaved fingers of the IDT.

10. The filter device according to claim 1, wherein the primary shear acoustic mode is a bulk shear mode where acoustic energy propagates along a direction substantially and/or predominantly orthogonal to the surface of the piezoelectric layer and transverse to a direction of an electric field created by the IDT.

11. The filter device according to claim 1, wherein each of the first and second bulk acoustic resonators further comprises:
a substrate; and
a dielectric layer disposed on the substrate and having a cavity disposed therein,
wherein the piezoelectric layer includes a diaphragm over the cavity,
wherein the IDT is disposed at a surface of the diaphragm that is opposite the cavity.

12. The filter device according to claim 1, further comprising at least one additional bulk acoustic resonator coupled in shunt between the first and second bulk acoustic resonators and coupled in parallel to the capacitor.

13. A filter device comprising:
a first plurality bulk acoustic resonators connected in series between a pair of ports;
a second plurality of bulk acoustic resonators connected in shunt with the first plurality of bulk acoustic resonators; and
a capacitor connected in shunt between ground and one bulk acoustic resonator of the plurality of bulk acoustic resonators that has a lowest anti-resonance frequency of the plurality of bulk acoustic resonators connected in series,
wherein each of the bulk acoustic resonators comprises:
a piezoelectric layer; and
an interdigital transducer (IDT) having a plurality of interleaved fingers at a surface of the piezoelectric layer,
wherein the piezoelectric layer and the IDT are configured such that a radio frequency signal applied to the IDT excites a primary shear acoustic mode in the piezoelectric layer.

14. The filter device according to claim 13, wherein the one bulk acoustic resonator comprises a pair of sub-resonators having a same stack as each other, and the capacitor bisects the pair of sub-resonators.

15. The filter device according to claim 13, wherein the primary shear acoustic mode is a bulk shear mode where acoustic energy propagates along a direction substantially and/or predominantly orthogonal to the surface of the piezoelectric layer and transverse to a direction of an electric field created by the IDT.

16. The filter device according to claim 14, further comprising a pair of additional capacitors that are connected in parallel to the pair of sub-resonators, respectively.

17. The filter device according to claim 16, wherein the pair of additional capacitors each have a capacitance greater than the capacitor connected between the ground and a node between the first and second bulk acoustic resonators.

18. The filter device according to claim 15, wherein:
the capacitor has a first conductor and a second conductor with the first conductor and the second conductor being separated by a gap having a distance in a range of 10 μm to 20 μm, and
at least a portion of the first conductor and at least a portion of the second conductor are disposed on a piezoelectric layer, wherein the piezoelectric layer includes an etched region beneath the gap.

19. The filter device according to claim 15, wherein the capacitor is an interdigital capacitor comprising a plurality of interdigitated capacitive fingers that extend in a direction substantially orthogonal to a direction of the plurality of interleaved fingers of the IDT.

20. A radio frequency module, comprising:
a radio frequency circuit;
a filter device coupled to the radio frequency circuit, the filter device and the radio frequency circuit being enclosed within a common package, wherein the filter device comprises:
a first port and a second port;
a first bulk acoustic resonator and a second bulk acoustic resonator connected in series between the first port and the second port, each of the first and second bulk acoustic resonators comprising a piezoelectric layer, and an interdigital transducer (IDT) having a plurality of interleaved fingers at a surface of the piezoelectric layer; and
a capacitor connected between ground and a node between the first bulk acoustic resonator and the second bulk acoustic resonator;
wherein the piezoelectric layer and the IDT are configured such that a radio frequency signal applied to the IDT excites a primary shear acoustic mode in the piezoelectric layer.
